(19) United States
(12) Patent Application Publication
(10) Pub. No.: US 2026/0150307 A1
(43) Pub. Date: May 28, 2026

(54) BACK END OF LINE INTEGRATED TRENCH CAPACITOR

(71) Applicant: TEXAS INSTRUMENTS INCORPORATED, Dallas, TX (US)

(72) Inventor: Christoph Dirnecker, ECHING/VIECHT (DE)

(21) Appl. No.: 18/960,207

(22) Filed: Nov. 26, 2024

(51) Int. Cl. H01L 29/94; H01L 27/06

(52) U.S. Cl. CPC H10D 1/665; H10D 84/204

(57) ABSTRACT

A method of forming an integrated circuit is disclosed herein. The method includes forming an electronic device over a substrate including a semiconductor material, forming a pre-metal dielectric layer over the electronic device, forming a trench through the pre-metal dielectric layer and into the substrate, forming a capacitor dielectric layer over the pre-metal dielectric layer and within the trench, and forming a conductive material layer over the capacitor dielectric layer and within the trench, wherein the conductive material layer forms a first plate of a trench capacitor and the semiconductor material of the substrate forms a second plate of the trench capacitor.

### FIELD

The present disclosure generally relates to integrated semiconductor devices, and more particularly, to integrated silicon trench capacitors.

### BACKGROUND

Integrated trench capacitors may be used in semiconductor devices to add capacitance to various integrated circuits. However, there are a number of issues that arise when attempting to integrate trench capacitors into a manufacturing process flow for an integrated circuit. For example, trench capacitors may be difficult to integrate into existing process flows. Improvements in integrating trench capacitors into semiconductor process flows are needed.

### SUMMARY

Disclosed herein are methods of forming trench capacitors and integrated circuits (ICs) including such capacitors. One example method includes forming an electronic device over a substrate, the substrate including a semiconductor material, forming a pre-metal dielectric layer over the electronic device, forming a trench through the pre-metal dielectric layer and into the substrate, forming a capacitor dielectric layer over the pre-metal dielectric layer and within the trench, and forming a conductive material layer over the capacitor dielectric layer and within the trench, wherein the conductive material layer forms a first plate of a trench capacitor and the semiconductor material of the substrate forms a second plate of the trench capacitor.

Another example method includes forming a silicide layer over a substrate, forming a pre-metal dielectric layer over the silicide layer, forming a trench through the pre-metal dielectric layer and into the substrate, forming a capacitor dielectric layer within the trench, and forming a conductive material layer within the trench, wherein a portion of the conductive material layer extends through the pre-metal dielectric layer and into the substrate.

Also disclosed herein is an IC device including a trench capacitor. The IC device includes a pre-metal dielectric layer disposed over a substrate, the substrate including a semiconductor material and a trench capacitor. The trench capacitor includes a capacitor dielectric layer extending into a plurality of trenches formed through the pre-metal dielectric layer and into the substrate and a conductive material extending into the plurality of trenches. The device further includes a metal layer disposed directly on the conductive material.

The foregoing features and elements may be combined in any combination, without exclusivity, unless expressly indicated herein otherwise. These features and elements as well as the operation of the disclosed examples will become more apparent in light of the following description and accompanying drawings.

### BRIEF DESCRIPTION OF THE DRAWINGS

Reference will now be made to the accompanying drawings, which are not necessarily drawn to scale. While the drawings illustrate various examples employing the principles described herein, the drawings do not limit the scope of the claims.

FIG. 1 illustrates a flowchart for a method of forming a semiconductor device, in accordance with various examples.

FIGS. 2A, 2B, 2C, 2D, 2E, 2F, 2G, 2H, 2I, 2J, 2K, 2L, 2M, 2N, 2O, 2P, 2Q, 2R, 2S, 2T, 2T′, 2U, 2V, 2W, and 2X illustrate cross-section views of various semiconductor devices, in accordance with the process of FIG. 1 and the various examples associated therewith.

FIG. 3 illustrates a flowchart for a method of forming a semiconductor device, in accordance with various examples.

FIGS. 4A, 4B, 4C, 4D, 4E, 4F, 4G, and 4H illustrate cross-section views of a semiconductor device, in accordance with the process of FIG. 3 and the various examples associated therewith.

FIG. 5 illustrates a cross-section view of a semiconductor device, in accordance with various examples.

FIGS. 6A, 6B, 6C, 6D, 6D′, and 6E illustrate plan views of a semiconductor device according to various examples.

### DETAILED DESCRIPTION

The following detailed description is presented for purposes of illustration and not of limitation. Benefits, advantages, and/or solutions to problems may be described with reference to various examples. The detailed description makes use of the various examples and refers to the accompanying drawings which illustrate the various examples described herein. The drawings, descriptions, and examples are described in sufficient detail to practice the disclosure. It is understood that connecting lines shown in the various drawings are intended to represent example functional relationships and/or physical couplings between various elements, but that other relationships and/or couplings are possible while remaining within the scope of the present disclosure. It will further be appreciated that the various drawings may not be drawn to scale in order to simplify and clarify the detailed description herein. Furthermore, it is understood that the descriptions and examples contained herein may permit the practice of other examples using logical, chemical, and/or mechanical changes without departing from the spirit and scope of this disclosure. For example, the steps recited in method and process descriptions may be executed in a different order, additional process steps may be added, and/or process steps may be removed while remaining within the scope of the present disclosure.

Any reference to singular items and/or examples includes plural items and/or examples and any reference to more than one item and/or example may include a singular item and/or example. Similarly, references to “a”, “an”, or “the” may include one or more of the referenced items, unless stated otherwise. Any reference to connected, coupled, fixed, attached, or the similar words and/or phrases may include partial, full, temporary, removable, permanent, or the other connection options. Any reference to contact, or similar phrase, may include minimal contact or reduced contact. All ranges used herein may include both the upper and lower values of the ranges, including ratio limits, that are disclosed herein. Stated values may include at least the variation that is expected within the field in which the present disclosure is practiced and as would be understood and accepted to include values that are within 10% of a stated value. Similarly, the terms “approximately”, “about”, or other similar terms represent an amount that is close to the stated value and that may still achieve the stated, or desired, result and/or perform the stated, or desired, function and may refer to an amount that is within 10% of the stated value. The term “substantially equal” with respect to two or more quantitative characteristics means values representing those characteristics are within ±2.5% of an average of the associated values.

The accompanying drawings, and detailed description of the drawings, include reference numerals that may be repeated across multiple examples. The repetition of reference numerals is intended for simplicity and clarity of description and is not intended to form or dictate a relationship between different examples described herein. The examples and descriptions provided herein are intended to be illustrative and not limiting beyond the scope of the claims. The use of terms such as “on” and “over” may indicate that a first feature is formed directly contacting a second feature or may indicate a relationship of the first feature and the second feature without direct contact between the two, such as additional features being formed between the two. For example, “on” may be used to indicate direct contact between the two and “over” may be used to indicate one or more intervening layers between the two.

Spatially relative terms such as, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of discussion herein and are not intended to limit the orientation of the various components, systems, apparatuses, devices, or other features. It is therefore understood and appreciated that the use of the spatially relative terms to practice this disclosure in different orientations remains within the scope of the present disclosure.

Generally, integrated circuit (IC) manufacturing processes can be divided into front end of line (FEOL) and back end of line (BEOL) processes. Generally, FEOL processes include forming the various IC components of the IC device, such as transistors, resistors, inductors, and capacitors, and BEOL processes include connecting the various components together through one or more layers of metal interconnects including silicides, contacts, metal lines and vias, among others. Among other differences between FEOL and BEOL processes, the temperatures of BEOL processes tend to be lower than the temperatures of FEOL processes. Conventionally, trench capacitors may be formed in part during FEOL processes along with the other IC components. For example, see U.S. Pat. Nos. 10,903,306 and 11,195,958, each of which is incorporated herein by reference in their entirety. However, conventional trench capacitors may not provide reasonable capacitor density for a given breakdown voltage requirement.

Various disclosed methods and devices of the present disclosure may be beneficially applied to switching DC-DC converters and other applications where ruggedness is required to enable device survival during load transients, short currents, negative current flow, and other exceptional conditions. While such examples may be expected to provide improvements in performance, such as improved safe-operating-area (SOA) and ruggedness while having preserved or even reduced specific on-resistance, no particular result is a requirement of the present invention unless explicitly recited in a particular claim.

Various disclosed methods and devices of the present disclosure may be beneficially applied to manufacturing IC devices that include integrated trench capacitors. While such examples may be expected to provide high capacitance density and/or reduced temperature of capacitor formation relative to some analogous baseline capacitors, no particular result is a requirement of the present invention unless explicitly recited in a particular claim.

Some described examples provide trench capacitors that may be added to a circuit design without affecting FEOL process flows related to other devices on the same substrate. Such capacitors may be formed after FEOL processes are completed. That is, the methods disclosed herein provide a modular approach to forming trench capacitors having increased capacitor density that meet high-voltage breakdown requirements. The devices formed using the methods disclosed herein incorporate a trench capacitor using a doped substrate as a “bottom plate” or “bottom electrode” and a metal material (e.g., tungsten (W)) as a “top plate” or “top electrode”. Forming the top plate from the metal material may provide lower series resistance than polysilicon core material. Furthermore, the first layer of metal (e.g., metal one (M1) layer) formed during the BEOL processing steps (e.g. a metallization process), is formed directly on the top plate of the trench capacitor. That is, there are no other intervening conductive features (e.g. conductive vias and/or contacts) between the first layer of metal (e.g., M1 layer) and the top plate of the trench capacitor. This direct contact may allow a higher capacitance density than baseline methods because there are no conductive features (e.g. conductive vias and/or contacts) to align to connect the top plate of the trench capacitor to the first layer of metal (e.g., M1 layer). Additionally, because the trench capacitors disclosed herein are formed using BEOL processing steps, the trench capacitors and other structures already formed on the device substrate are exposed to lower temperatures than would otherwise occur were the trench capacitors to be formed using some FEOL process steps. Among other benefits, this aspect is expected to reduce the risk of defect formation caused by mechanical stress associated with the higher FEOL process temperatures.

As disclosed herein, the trench capacitors are formed after IC components are formed during the FEOL processes and after a silicide layer and/or a pre-metal dielectric layer are formed in preparation for forming contacts and metal lines between the IC components during the BEOL processes. A trench is formed through the pre-metal dielectric layer and the silicide layer and into the substrate. A capacitor dielectric is formed over the pre-metal dielectric layer and in the trench, including along sidewalls and bottom surfaces of the trench. A conductive material layer is formed over the capacitor dielectric layer, including in the trench, to form a capacitor plate (e.g., the top plate). A second trench (e.g., a contact hole) is formed through the pre-metal dielectric layer to expose the silicide layer. A contact feature (e.g., metal contact) is formed in the second trench and on the silicide layer that is disposed over the doped substrate (e.g., the bottom plate). Then the first metal layer (e.g., M1 layer) of the BEOL metallization process is formed directly on the capacitor plate (e.g., the top plate). This is in contrast to trench capacitors formed using FEOL processing steps, for which the metal interconnections typically include an additional vertical interconnect (or “contact”) to connect BEOL interconnect metal levels to the capacitor electrodes. Additional process steps and benefits will be described in further detail below.

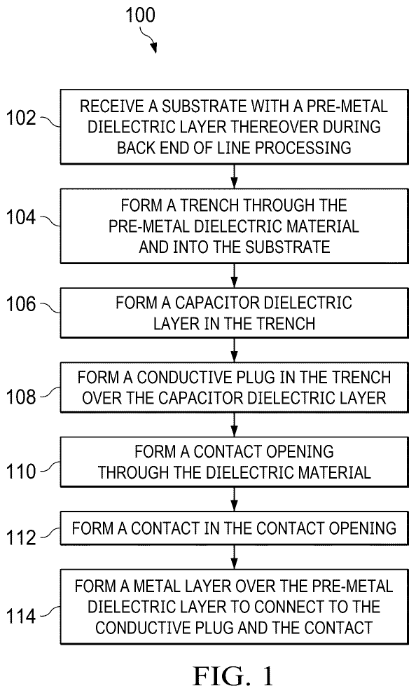

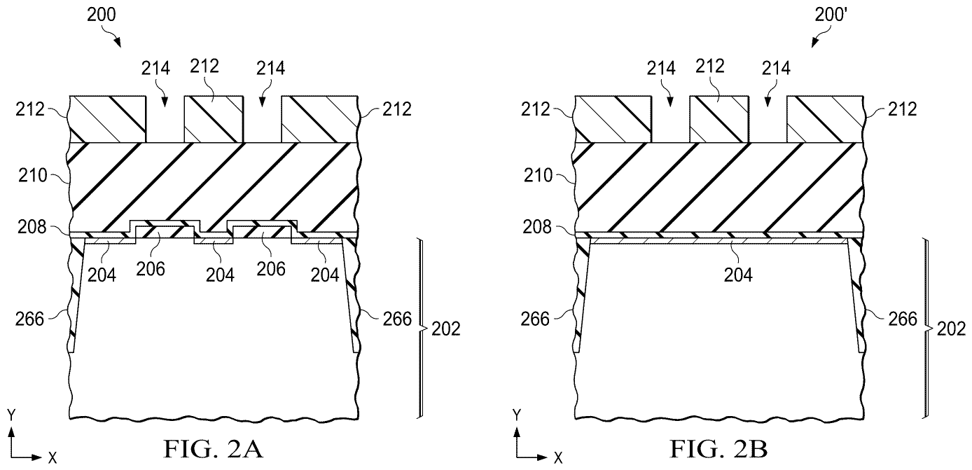

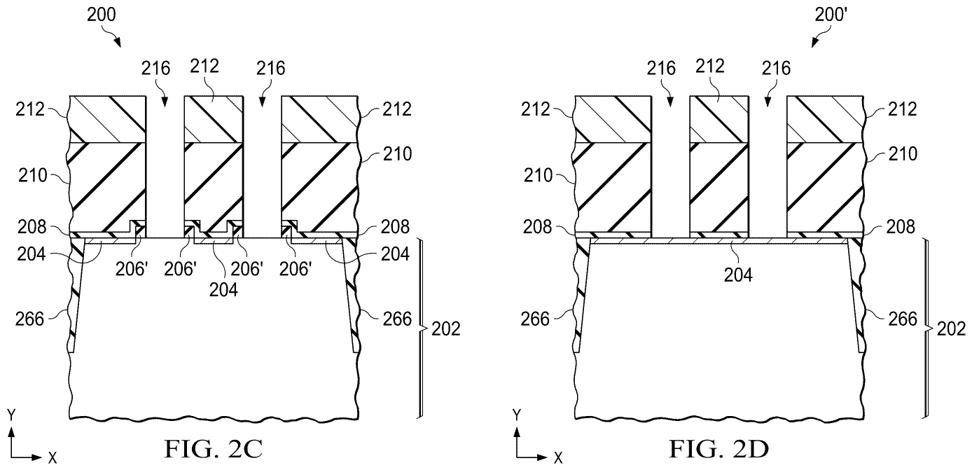

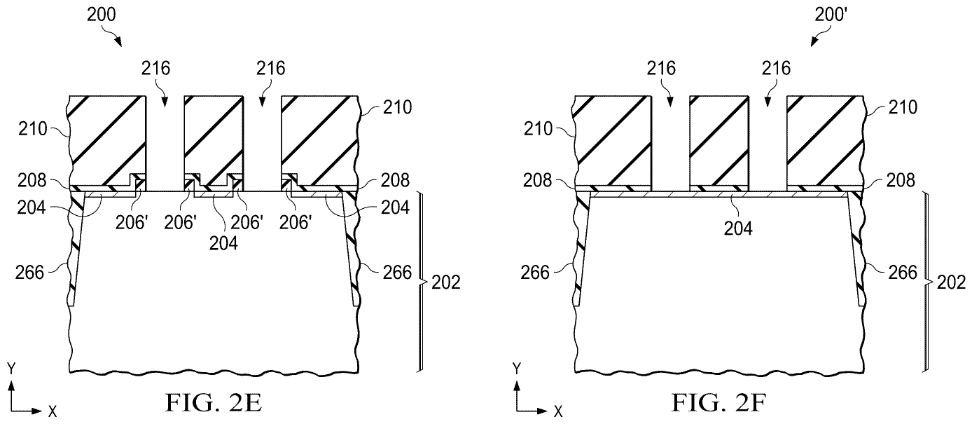

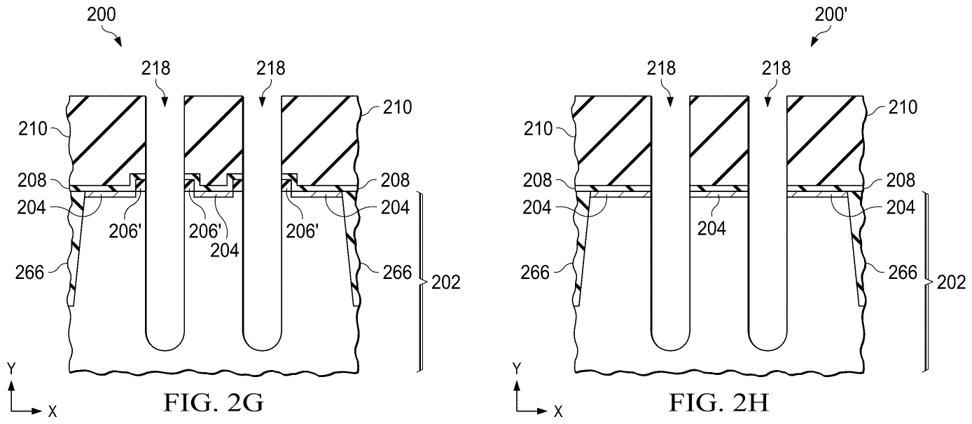

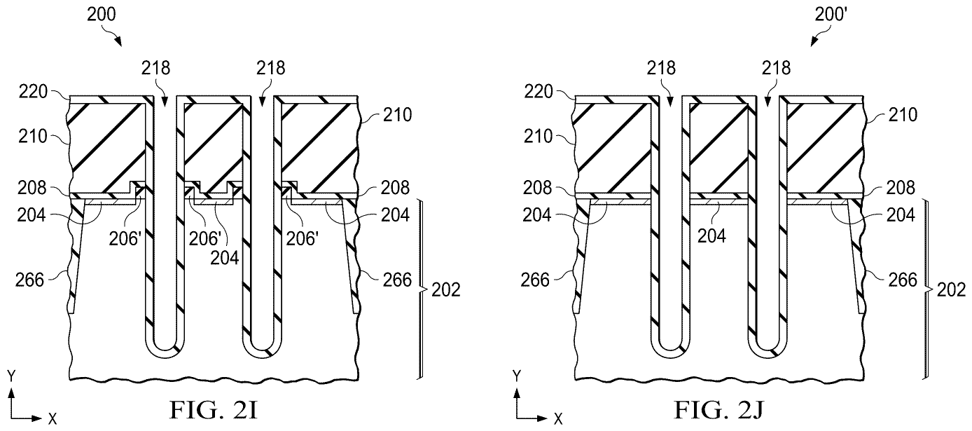

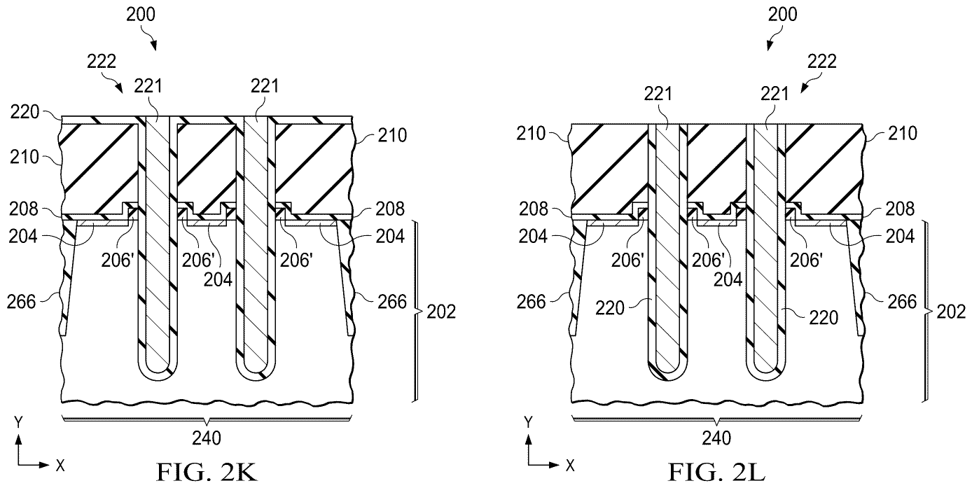

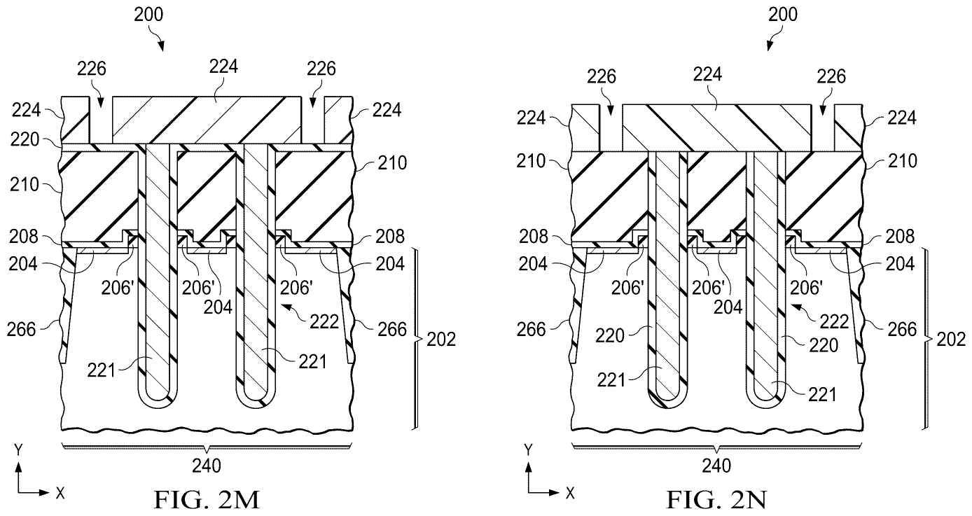

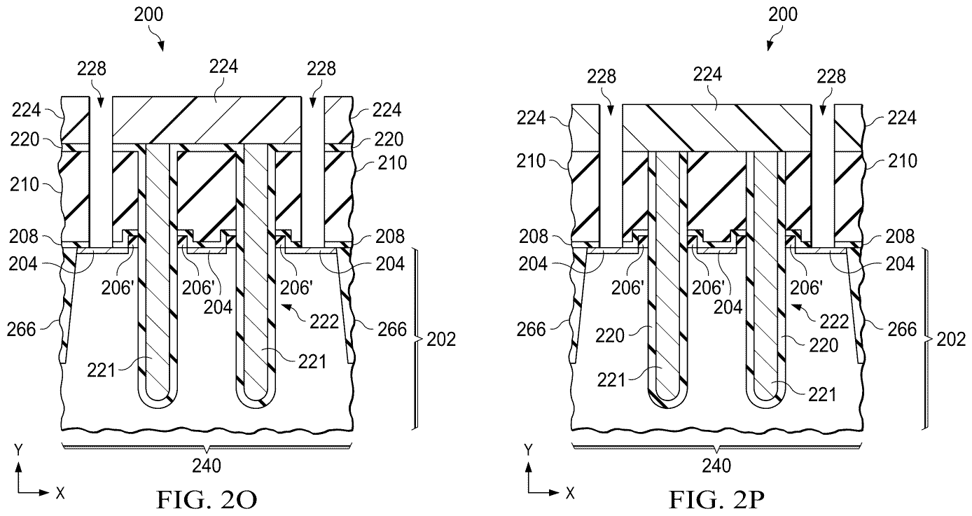

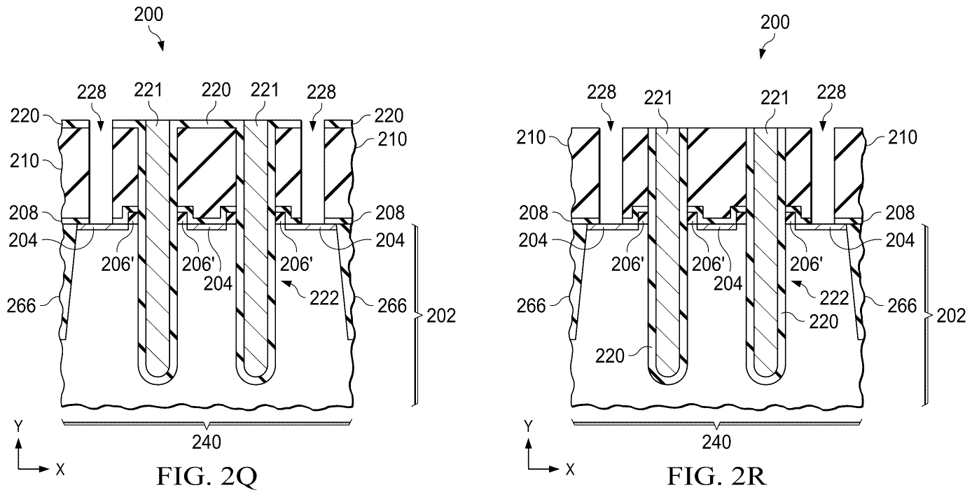

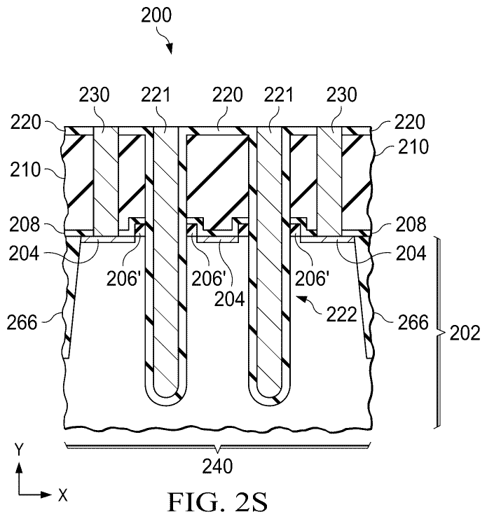

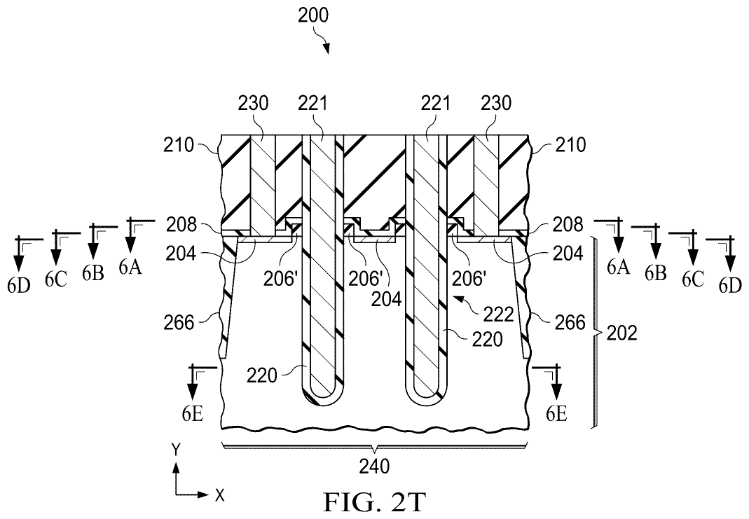

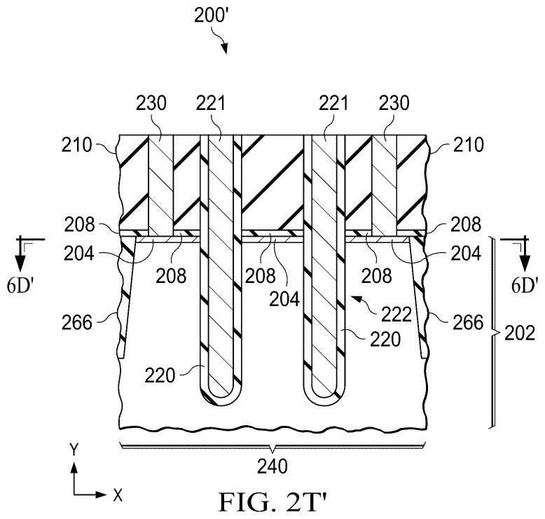

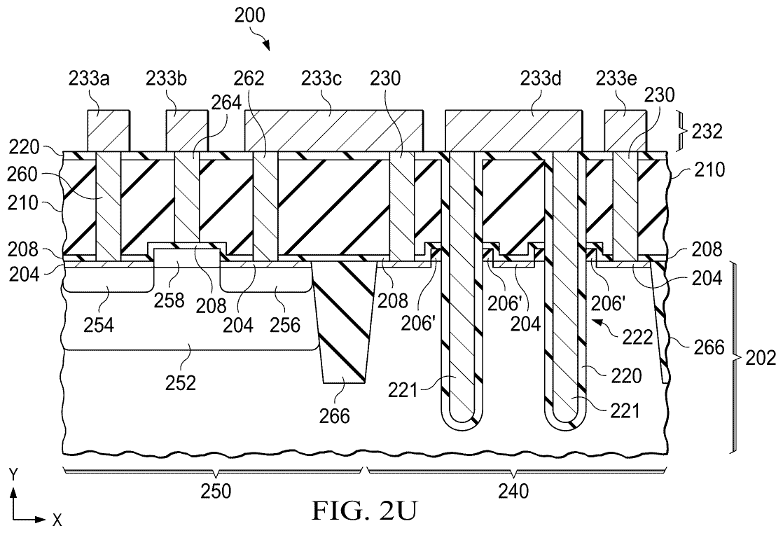

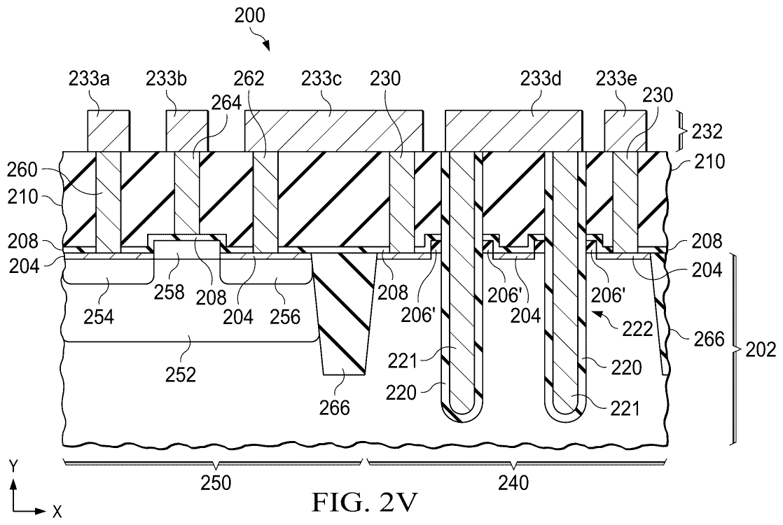

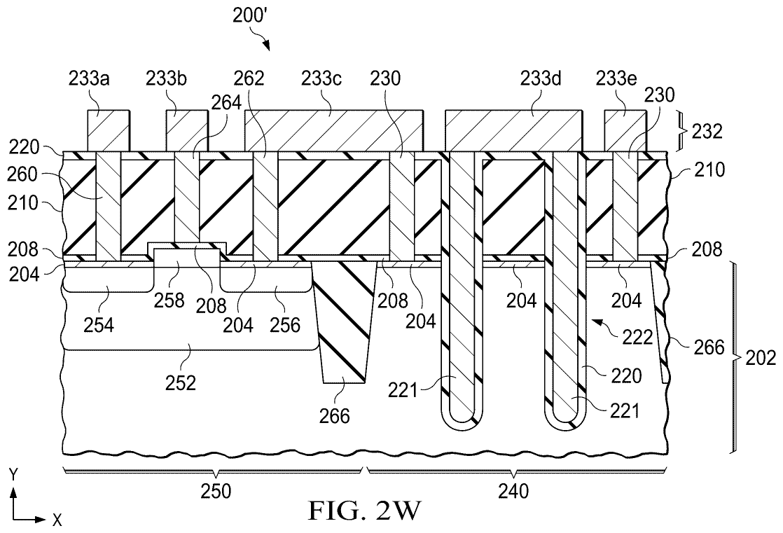

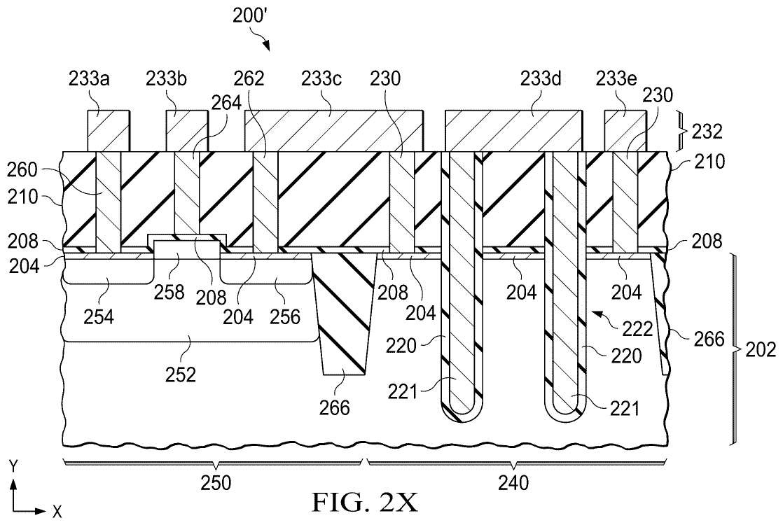

Referring now to FIG. 1, a flow diagram of a method 100 for forming a trench capacitor in a substrate during BEOL processing is illustrated, in accordance with various examples of the present disclosure. Prior to the steps of method 100 the substrate has completed FEOL processing. FEOL processing may be regarded as including steps to form components (e.g., electronic devices) including transistors, diffusion resistors, etc., and ending with formation of a silicide layer to provide ohmic connections to such device. BEOL processing may be regarded as including those process steps needed to form metallic interconnects and dielectric layers used to route signals between the various devices and to input/output (I/O) terminals of the integrated circuit. In various examples, and as used throughout below description, the transistors may include field effect transistors (FETs), bipolar transistors, bipolar plus complementary metal oxide semiconductor (BiCMOS) transistors, other transistors, or a combination thereof. Additional processes can be provided before, during, and after method 100. As discussed below, method 100 is described with reference to FIGS. 2A-2X.

In that regard, FIGS. 2A-2X are diagrammatic cross-sectional views of devices 200 and 200′ at various stages of BEOL fabrication (such as those associated with method 100 of FIG. 1) according to various aspects of the present disclosure. In various examples, devices 200 and 200′ may be an integrated circuit having completed FEOL processing. For ease of discussion, FIGS. 2A-2T are illustrated and described without showing other components of the integrated circuit of device 200. FIGS. 2U-2X illustrate devices 200 and 200′ having a FET formed via FEOL processing steps adjacent to the trench capacitor that is formed by method 100 during BEOL processing steps as illustrated in FIGS. 2A-2X. Moreover, as discussed in more detail below, the process of forming a trench capacitor in device 200 includes the use of a silicide blocking layer while the process of forming a trench capacitor in device 200′ occurs without the use of a silicide blocking layer. As such, FIGS. 2A, 2C, 2E, 2G, 2I, 2K, 2L, 2M, 2N, 2O, 2P, 2Q, 2R, 2S, 2T, 2U, and 2V illustrate the process of forming device 200 that includes using a silicide blocking layer while FIGS. 2B, 2D, 2F, 2H, 2J, 2W and 2X highlight some of the differences in forming device 200′ without using a silicide blocking layer. Additional features can be added to devices 200 and 200′ and some features described below can be replaced, modified, or eliminated in other examples of devices 200 and 200′.

At step 102 of FIG. 1, a substrate with a pre-metal dielectric layer thereover is received during BEOL processing. As shown in FIGS. 2A and 2B, examples of device 200 and 200′ are illustrated being received after completing FEOL processing steps, and after completing one or more BEOL processes. In some examples, one or more transistors, resistors and/or other components (e.g., FET 250 in FIGS. 2U-2X) are formed on devices 200 and 200′ during FEOL processing. That is, devices 200 and 200′ shown in FIGS. 2A-2T includes one or more such devices (e.g., FET 250 in FIGS. 2U-2X) previously formed during FEOL processing and before step 102. In some examples, one or more BEOL processing steps may have already occurred on devices 200 and 200′ such as the formation of a pre-metal dielectric layer and/or other BEOL material layers.

In some examples, as illustrated in FIG. 2A, device 200 includes a substrate 202, a silicide layer 204, a silicide blocking layer 206, a dielectric liner 208, a pre-metal dielectric layer (“PMD”) 210, and a first patterned resist layer 212 having openings 214 formed therethrough. Substrate 202 may include a bulk semiconductor substrate, a semiconductor-on-insulator (SOI) substrate, or any other appropriate substrate. For example, the substrate 202 may be or include a bulk silicon wafer. In various examples, substrate 202 may include a dielectric material, an epitaxially grown material, and/or any other any material and/or layer on which the process described herein may be performed. For example, substrate 202 may include one or more epitaxially grown layers disposed on a semiconductor substrate (e.g., silicon substrate). In some examples, substrate 202, including epitaxially grown layers disposed thereon, have doped regions (or wells) formed therein such that these doped regions of substrate 202 form one of the capacitor plates of the later formed trench capacitor as described in more detail below.

Silicide layer 204 and silicide blocking layer 206 are formed over a top surface of substrate 202. As shown, in various examples, silicide layer 204 and silicide blocking layer 206 may be interspersed along the top surface of substrate 202 in the plane of the sectional view. That is, silicide blocking layer 206 blocks/prevents the formation of silicide layer 204 from occurring where silicide blocking layer 206 is present along the top surface of substrate 202. In some examples, silicide layer 204 may be formed of silicon and at least one of cobalt, nickel, tungsten or titanium (e.g., CoSi₂, Ni₂Si, WSi₂ and/or TiSi₂). Silicide layer 204 provides an ohmic connection for subsequently formed contacts thereover and a low sheet resistance layer at the surface of the semiconductor substrate. In some examples, silicide blocking layer 206 includes an oxide material and/or nitride material that blocks or prevents the formation of silicide. In some examples, silicide blocking layer 206 may include silicon dioxide, silicon nitride, silicon oxy-nitride, other dielectric films, or a combination thereof. As described below, in some examples, silicide blocking layer 206 is positioned over portions of substrate 202 where the trench capacitor is to be formed therethrough.

Optional dielectric liner 208 is formed over both silicide layer 204 and silicide blocking layer 206, and PMD 210 is formed over dielectric liner 208. Dielectric liner 208 may include one or more layers of a dielectric material including an oxide and/or nitride material such a silicon oxide and/or silicon nitride. PMD 210 may include one or more layers of dielectric material. The one or more layers of dielectric material of PMD 210 may include oxide, nitride and/or carbide materials such as silicon oxide, silicon nitride, silicon oxy-nitride, and/or silicon carbide, the like, or a combination thereof). The use of the term silicon oxide throughout this disclosure includes materials such as silicon monoxide (SiO) and/or silicon dioxide (SiO₂) and/or a non-stoichiometric mixture of the two. In various examples, a thickness of PMD 210 may be determined based on one or more design parameters of device 200. Accordingly, the initial thickness of PMD 210 may be greater than the designed thickness to compensate for material loss during one or more of the process steps described below.

First patterned resist layer 212 is formed over PMD 210. As shown, first patterned resist layer 212 is formed directly on PMD 210 and has openings 214 exposing a top surface of PMD 210. First patterned resist layer 212 may be any resist material including either positive or negative photoresist materials, or may be a suitably patterned hardmask.

As discussed above, FIG. 2B illustrates device 200′ that is processed without using a silicide blocking layer. In that regard, device 200′ includes similar layers as device 200 such as substrate 202, silicide layer 204, dielectric liner 208, PMD 210, and first patterned resist layer 212. The description of these layers is similar as the description above for device 200. As shown, device 200′ includes silicide layer 204 extending over the top surface of substrate 202. Optionally the silicide layer 204 may be continuous. That is, unlike device 200, silicide layer 204 of device 200′ is uninterrupted by a silicide blocking layer over the top surface of substrate 202.

At step 104 of FIG. 1, a trench is formed through the pre-dielectric material and into the substrate. As shown in FIGS. 2C-2H, dielectric trenches 216 and extended trenches 218 are formed in devices 200 and 200′. In some examples, as illustrated in FIG. 2C, dielectric trenches 216 of device 200 are formed through PMD 210, dielectric liner 208, and silicide blocking layer 206 using first patterned resist layer 212 and openings 214 as a mask.

Specifically, as discussed above, dielectric trenches 216 in device 200 are formed through the silicide blocking layer 206 such that portions 206′ of silicide blocking layer 206 remain after the trench formation. As discussed in more detail below, these portions 206′ increase the distance (e.g. dielectric buffer) between the silicide layer 204 and the capacitor plate, or terminal, subsequently formed in dielectric trenches 216. In some examples, the remaining portions 206′ of silicide blocking layer 206 prevents silicide layer 204 from being exposed during trench etching processes which may reduce cross contamination of the silicide materials from silicide layer 204 into substrate 202 (e.g., incorporation of silicide materials in trench walls). In various examples, reducing cross contamination improves the quality of the silicon trench capacitor (e.g., higher breakdown voltage, less current leakage, etc.). After the formation of dielectric trenches 216, portions (e.g., top surface) of substrate 202 are exposed within the trenches.

With respect to device 200′, as illustrated in FIG. 2D, dielectric trenches 216 are formed through PMD 210 and dielectric liner 208 using first patterned resist layer 212 and openings 214 as a mask. After the formation of dielectric trenches 216 in device 200′, portions of silicide layer 204 are exposed within openings 214. As discussed in more detail below, later processing steps extend dielectric trenches 216 through silicide layer 204 into substrate 202 such that portions of a capacitor dielectric layer subsequently formed in the trenches interface with remaining portions of silicide layer 204. That is, unlike device 200 where silicide blocking layer provides an extra buffer, device 200′ allows for the silicide layer 204 to interface directly with a capacitor dielectric layer subsequently formed in the trenches.

In various examples, one or more etching processes may be used to form dielectric trenches 216 in devices 200 and 200′. In various examples, the one or more etching processes may include a dry etch, a wet etch, or a combination thereof. In various examples, one or more etching process may be used to etch through PMD 210, dielectric liner 208, and/or silicide blocking layer 206 to form dielectric trenches 216 in device 200. In various other examples, one or more etching process may be used to etch through PMD 210 and dielectric liner 208 to form dielectric trenches 216 in device 200′. In various examples, a first etching process may be used to form dielectric trenches 216 through PMD 210. In various examples, a second etching process may be used to extend dielectric trenches 216 through dielectric liner 208. In various examples, a third etching process may be used to extend dielectric trenches 216 through silicide blocking layer 206 in device 200.

As shown in FIGS. 2E and 2F, first patterned resist layer 212 is removed from devices 200 and 200′. In some examples, first patterned resist layer 212 may be removed via a plasma ashing process. In some other examples, as describe below, first patterned resist layer 212 may be removed in a subsequent process step of method 100.

As shown in FIGS. 2G and 2H, dielectric trenches 216 are extended into substrate 202 forming extended trenches 218 in devices 200 and 200′. In various examples, extended trenches 218 may be formed following removal of first patterned resist layer 212. In various examples, extended trenches 218 may be formed before removing first patterned resist layer 212. In device 200, as illustrated in FIG. 2G, dielectric trenches 216 are extended by removing portions of substrate 202 to form extended trenches 218. In device 200′, as illustrated in FIG. 2H, dielectric trenches 216 are extended by removing portions of silicide layer 204 and substrate 202 to form extended trenches 218.

In various examples, one or more etching processes may be used to form extended trenches 218 in devices 200 and 200′. In various examples, the one or more etching processes may include a wet etch, a dry etch, or a combination thereof. In some examples, with respect to device 200′, a silicide etch process may be performed followed by a silicon etch process where substrate 202 includes silicon material (e.g., FIG. 2H). The silicide etch process removes portions of silicide layer 204 to expose a top surface of substrate 202 and the silicon etch process extends extended trenches 218 into substrate 202. In some examples, with respect to device 200, a silicon etch process may be performed to remove portions of substrate 202 (e.g., silicon substrate) without the silicide etch process (e.g., FIG. 2G) as the previously removed portions of silicide blocking layer 206 prevented silicide formation in the areas where extended trenches are formed therethrough. In some examples, the one or more etching processes may include one or more dry etch processes including the use of chlorine (Cl), fluorine (F), bromine (Br), other etchants, or a combination thereof.

As described above, in some examples, substrate 202, includes epitaxially grown layers disposed thereon, having doped regions (or wells) formed therein such that these doped regions of substrate 202 form one of the capacitor plates of the later formed trench capacitor as described in more detail below. In various examples, after forming extended trenches 218, an angled implantation process may be performed on the sidewall surfaces of extended trenches 218. (See, e.g., U.S. Pat. No. 11,195,958.) Such an implantation process implants a dopant (e.g., arsenic (As), phosphorus (P), etc.) into the sidewalls of extended trenches 218. In some examples, the implantation process may include a tilted implantation process. The implanted dopant in sidewalls of extended trenches 218 may help reduce serial resistance of the portions of substrate 202 that form one of the capacitor plates of the later formed trench capacitor.

At step 106 of FIG. 1, a capacitor dielectric layer is formed in the trench. As shown in FIGS. 2I and 2J, a capacitor dielectric layer 220 is formed in extended trenches 218 in devices 200 and 200′. Specifically, capacitor dielectric layer 220 is formed over PMD 210 and in extended trenches 218, including along sidewalls and bottom surfaces of extended trenches 218. In some examples of device 200, as shown in FIG. 2I, capacitor dielectric layer 220 is formed along sidewalls of PMD 210, sidewalls of dielectric liner 208, sidewalls of portions 206′ of silicide blocking layer 206, and sidewalls and bottom surfaces of substrate 202. In some other examples of device 200′, as shown in FIG. 2J, capacitor dielectric layer 220 is formed along sidewalls of PMD 210, sidewalls of dielectric liner 208, sidewalls of silicide layer 204, and sidewalls and bottom surfaces of substrate 202.

In various examples, capacitor dielectric layer 220 may be formed by one or more processes such as chemical vapor deposition (CVD), physical vapor deposition (PVD), atomic layer deposition (ALD), thermal oxidation, other suitable formation processes, or a combination thereof. In various examples, capacitor dielectric layer 220 may be formed as one or more layers formed during one or more process steps. In various examples, capacitor dielectric layer 220 may include silicon oxide, silicon nitride, silicon oxynitride, aluminum oxide, any other high-k dielectric material, other suitable dielectric material, or a combination thereof. In some examples, capacitor dielectric layer 220 may be a multilayered film including an oxide material/nitride material/oxide material configuration.

FIGS. 2K-2X and their descriptions below will be with reference to the examples of device 200 that include silicide blocking layer 206 and not include examples of device 200′ that is formed without silicide blocking layer 206. This is done for simplicity and ease of discussion going forward. Specifically, the steps of method 100 moving forward are similar whether or not silicide blocking layer 206 is present. Accordingly, to simplify the discussion, the examples of device 200′ without silicide blocking layer 206 will not be illustrated in FIGS. 2K-2X (except for FIG. 2T′).

At step 108 of FIG. 1, a conductive plug is formed in the trench over the capacitor dielectric layer. As shown in FIG. 2K, a capacitor plate 222 including conductive plugs 221 is formed in extended trenches 218. In some examples, a conductive material layer (e.g., electrically conductive trench-fill material layer(s) and/or barrier layers) is formed over capacitor dielectric layer 220 and within extended trenches 218. A planarization process (e.g., a chemical mechanical polishing (CMP) process) is then performed to remove the overburden portions of the conductive material layer to form capacitor plate 222. In some examples, as shown in FIG. 2K, the planarization process removes the overburden portions of the conductive material layer and exposes capacitor dielectric layer 220 that is disposed over PMD 210. In some other examples, as shown in FIG. 2L, the planarization process removes the overburdened portions of the conductive material layer disposed over PMD 210 as well as portions of capacitor dielectric layer 220 that are disposed over PMD 210 to expose PMD 210. As shown, after the planarization process of the conductive material layer, one or more conductive plugs 221 are disposed in extended trenches 218. The capacitor plate 222 includes the one or more conductive plugs 221 connected electrically in parallel, as described further below.

In various examples, conductive plugs 221 of capacitor plate 222 may include one or more metal and/or metal alloys layers. In various examples, conductive plugs 221 of capacitor plate 222 may include tungsten metal. In various examples, conductive plugs 221 of capacitor plate 222 may be a multilayered material layer that includes one or more barrier layers and/or electrically conductive trench-fill material layer(s). For example, conductive plugs 221 of capacitor plate 222 may include tantalum (Ta), titanium (Ti), and/or titanium nitride (TiN) barrier layers and a W, TiW, and/or TaN conductive fill material layer. In various other examples, conductive plugs 221 of capacitor plate 222 may include aluminum (Al), copper (Cu), doped polycrystalline silicon, alloys thereof, or other suitable conductive materials. In various examples, capacitor plate 222 may be formed using one or more processes. In various examples, the one or more processes used to form capacitor plate 222 may include a chemical vapor deposition (CVD) process, a physical vapor deposition (PVD) process, a sputtering process, an evaporation process, other suitable processes, or combinations thereof.

As discussed in further detail below, and as shown in FIGS. 2K and 2L, a trench capacitor 240 is formed in device 200 as a result of the formation of capacitor plate 222. Specifically, capacitor plate 222 and substrate 202 form the capacitor plates of trench capacitor 240. In that regard, as discussed above, substrate 202, including epitaxially grown layers disposed thereon, may have doped regions (or wells) formed therein such that these doped regions of substrate 202 form a first capacitor plate (e.g., bottom capacitor plate) of trench capacitor 240. Also, in some examples, capacitor plate 222 forms a second plate (e.g., top capacitor plate) of trench capacitor 240. As shown, trench capacitor 240 further includes capacitor dielectric layer 220 positioned between substrate 202 (e.g., first capacitor plate) and capacitor plate 222 (e.g. second capacitor plate) thereby isolating the two plates from each other.

Still further, as described above and shown in FIGS. 2K and 2L, device 200 includes portions 206′ of silicide blocking layer 206 that interface with capacitor dielectric layer 220. As a result, the distance between silicide layer 204 and capacitor plate 222 is increased, in-part, because of portions 206′ of silicide blocking layer 206. That is, these portions 206′ of silicide blocking layer 206 increase the distance (e.g. dielectric buffer) between the silicide layer 204 and the capacitor plate 222. In some examples, portions 206′ of silicide blocking layer 206 prevent silicide layer 204 from being exposed during trench etching processes which may reduce cross contamination of the silicide materials from silicide layer 204 into substrate 202 (e.g., incorporation of silicide materials in trench walls). In various examples, reducing cross contamination improves the quality of the silicon trench capacitor (e.g., higher breakdown voltage, less current leakage, etc.).

At step 110 of FIG. 1, a contact opening is formed through the dielectric material. As shown in FIGS. 2M-2P, contact openings 228 are formed through PMD 210. A second patterned photoresist layer 224 is formed over device 200 and has openings 226 formed therethrough exposing underlying areas where contact openings are subsequently formed therethrough. In some examples, as shown in FIG. 2M, second patterned photoresist layer 224 is formed over capacitor dielectric layer 220. That is, FIG. 2M follows the process of device 200 from FIG. 2K where the planarization process stopped at the capacitor dielectric layer 220 such that the second patterned photoresist layer 224 is formed thereon. As such, in FIG. 2M, openings 226 of second patterned photoresist layer 224 expose portions of the underlying capacitor dielectric layer 220. In some other examples, as shown in FIG. 2N, second patterned photoresist layer 224 is formed over PMD 210. That is, FIG. 2N follows the process of device 200 from FIG. 2L where the planarization process removes capacitor dielectric layer 220 to expose the underlying PMD 210 such that the second patterned photoresist layer 224 is formed on the PMD 210. As such, in FIG. 2N, openings 226 of second patterned photoresist layer 224 expose portions of the underlying PMD 210.

As shown in FIGS. 2O and 2P, contact openings 228 are formed through PMD 210 using second patterned photoresist layer 224 as a mask. In some examples, as shown in FIG. 2O, contact openings 228 are formed through capacitor dielectric layer 220, PMD 210, and dielectric liner 208 thereby exposing silicide layer 204. That is, FIG. 2O follows the process of device 200 from FIG. 2M where the capacitor dielectric layer 220 is disposed over the PMD 210 such that contact openings 228 extend through various layers including the portions of capacitor dielectric layer 220 disposed over PMD 210. As such, portions of capacitor dielectric layer 220 define portions of the sidewalls of contact openings 228. In some other examples, as illustrated in FIG. 2P, contact openings 228 are formed through PMD 210 and dielectric liner 208, exposing silicide layer 204. In various examples, one or more etching processes may be used to etch through PMD 210 and dielectric liner 208. That is, FIG. 2P follows the process of device 200 from FIG. 2N where the capacitor dielectric layer 220 has been removed from over the PMD 210. As such, unlike FIG. 2O, sidewalls of contact openings 228 are defined in part by discontinuous portions of the capacitor dielectric layer 220, as this layer has been removed from over PMD 210 as discussed above with respect to FIG. 2L. The one or more etching processes for forming contact openings 228 may include a wet etch process, a dry etch process, other suitable processes, or a combination thereof. In various examples, the one or more etching processes may be similar to those described above in FIGS. 2A-2F.

As shown in FIGS. 2Q and 2R, second patterned photoresist layer 224 may be removed from device 200 prior to forming contacts 230. In various examples, as shown in FIG. 2Q, second patterned photoresist layer 224 may be removed, exposing capacitor dielectric layer 220. That is, FIG. 2Q follows the process of device 200 from FIG. 2O where the capacitor dielectric layer 220 is disposed over the PMD 210 such that the removal of second patterned photoresist layer 224 exposes portions of capacitor dielectric layer 220 disposed over PMD 210. In some other examples, as shown in FIG. 2R, second patterned photoresist layer 224 may be removed, exposing PMD 210. That is, FIG. 2R follows the process of device 200 from FIG. 2P where the capacitor dielectric layer 220 has been removed from over the PMD 210. As such, the removal of second patterned photoresist layer 224 exposes the underlying PMD 210. Additionally, as shown in FIGS. 2Q and 2R, removal of second patterned photoresist layer 224 further exposes conductive plugs 221 of capacitor plate 222. In various examples, second patterned photoresist layer 224 may be removed by one or more processes including a plasma ashing process.

At step 112, contacts are formed in the contact openings. As shown in FIGS. 2S and 2T, a conductive material layer (e.g., an electrically conductive trench-fill material and/or barrier layers) is formed in contact openings 228 and a planarization process is performed to form contacts 230. In various examples, the conductive material layer may be similar to the conductive material layer used in capacitor plate 222 that is described above in FIGS. 2K and 2L. In various other examples, the conductive material layer of contacts 230 may include (i) one or more metal-barrier and/or adhesion layers (e.g., TiN, TaN, the like, or a combination thereof) conformally in a respective contact openings 228 and (ii) a fill metal (e.g., Al, Cu, W, the like, or a combination thereof) over and/or on the metal-barrier and/or adhesion layer(s). In various examples, the planarization process used to form contacts 230 may include one or more CMP processes and/or other suitable planarization processes. In some examples, as shown in FIG. 2S, the planarization process may be performed to remove excess conductive material (e.g. the overburden of conductive material), exposing the top surface of capacitor dielectric layer 220. That is, FIG. 2S follows the process of device 200 from FIG. 2Q where the capacitor dielectric layer 220 is disposed over the PMD 210 such that the respective top surfaces of capacitor dielectric layer 220 and contacts 230 are planarized. In some other examples, method 100 may proceed from FIG. 2Q to FIG. 2T where the planarization process may be performed to remove excess conductive material (e.g. the overburden of conductive material) used to form contacts 230, some of the conductive material from capacitor plate 222 and remove capacitor dielectric layer 220, exposing the top surface of PMD 210. In some other examples, method 100 may proceed from FIG. 2R to FIG. 2T where the planarization process may be performed to remove excess conductive material (e.g. the overburden of conductive material) used to form contacts 230, exposing the top surface of PMD 210. That is, in this example, FIG. 2T follows the process of device 200 from FIG. 2R where the capacitor dielectric layer 220 has already been re moved from over PMD 210 such that the respective top surfaces of PMD 210 and contacts 230 are planarized.

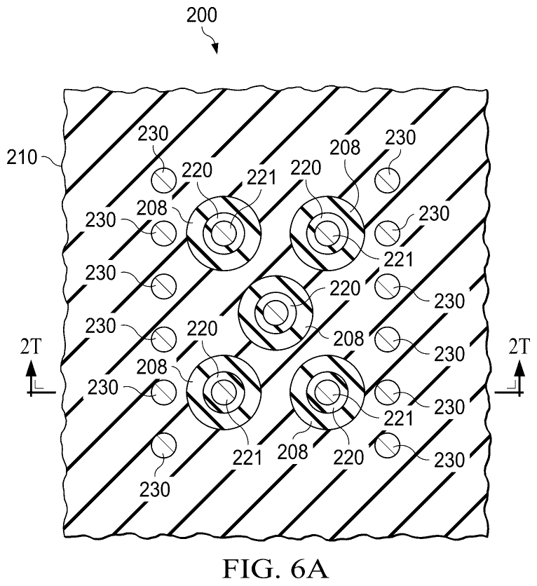

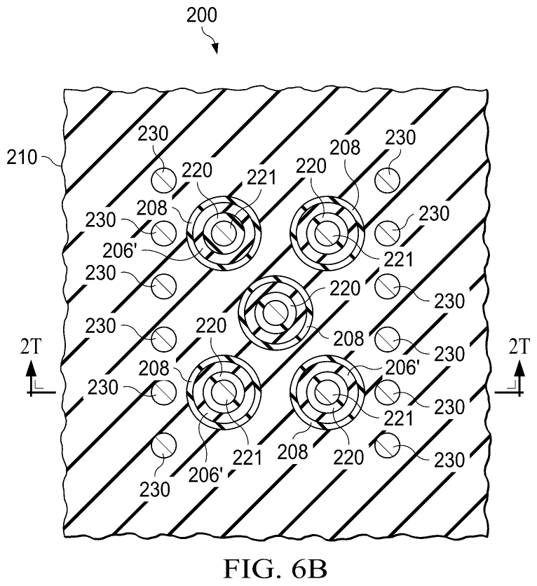

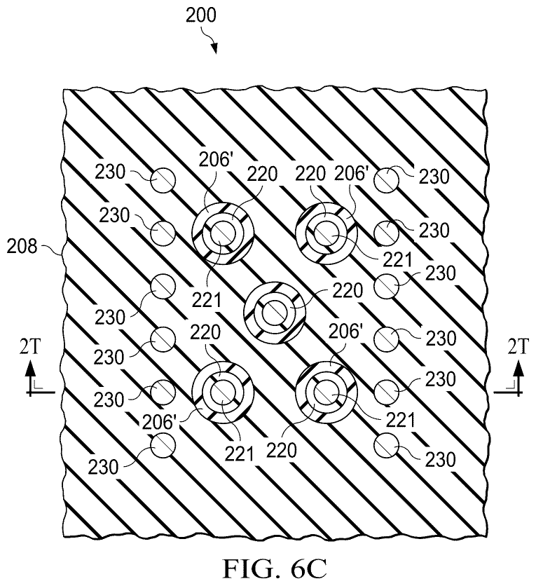

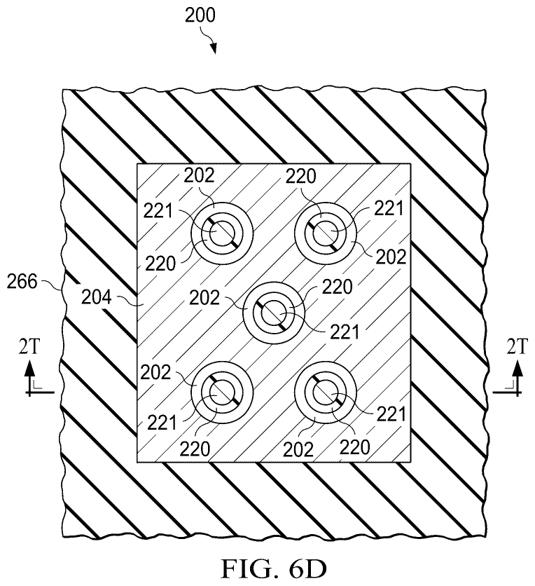

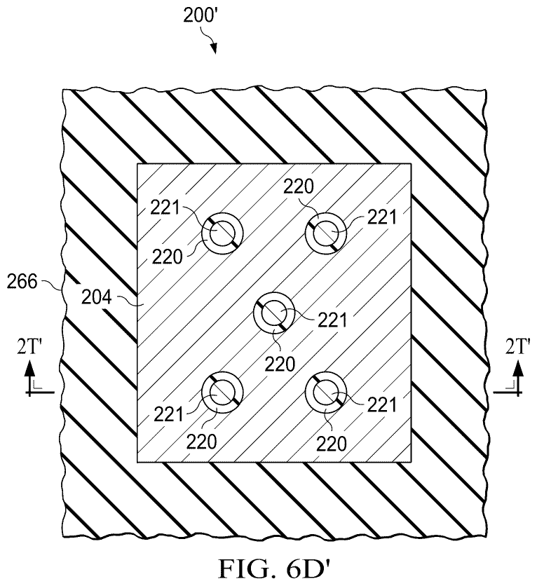

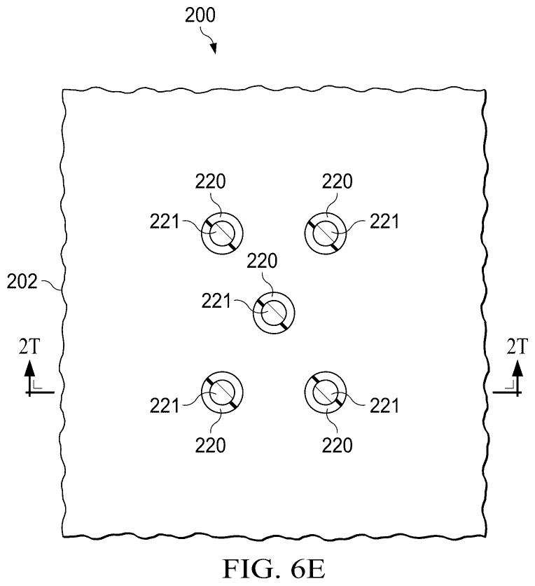

Referring now to FIGS. 6A-6E, in conjunction with FIGS. 2T and 2T′, plan views of device 200 or device 200′ are shown. Each of FIGS. 6A-6E shows a different top down view (e.g., in the negative y-direction) at a given depth as indicated in FIGS. 2T and 2T′. In that regard, FIGS. 6A, 6B, 6C, 6D, and 6E are top down views of device 200 while FIG. 6D′ shows a top down view of device 200′.

With respect to FIG. 6A, a top down view for device 200 at the elevation indicated in FIG. 2T by view line 6A is shown. In that regard, FIG. 6A shows a top down view at a level in device 200 through PMD 210 in which conductive plugs 221, capacitor dielectric layer 220, and contacts 230 are formed therethrough. As shown, capacitor dielectric layer 220 and conductive plugs 221 are further formed through dielectric liner 208, as described above. Moreover, in some examples, as shown, conductive plugs 221 and/or contacts 230 may have a circular cross-sectional shape. In other examples, conductive plugs 221 and/or contacts 230 may have other cross-sectional shapes such as square, oval, triangular, rectangular, the like, or a combination thereof.

In various examples, as shown in FIG. 6A, contacts 230 may be aligned in a linear row (or column). In other examples, contacts 230 may include contacts not aligned in a linear row (or column) such that one or more contacts are offset from an adjacent contact. Additionally, there may be any number of contacts 230 and the exact number shown in FIG. 6A is for purpose of example and should not be construed as limiting.

In various examples, as shown in FIG. 6A, conductive plugs 221 may form a checkerboard pattern (e.g., offset from each other) or hexagonal array. In other examples, conductive plugs 221 may be aligned in any manner with respect to each other including in rows and/or columns. In other examples, conductive plugs 221 may include plugs that are not aligned in a linear row (or column) such that one or more conductive plugs are offset from an adjacent conductive plug. Additionally, there may be any number of conductive plugs 221 and the exact number shown in FIG. 6A is for the purpose of example and should not be construed as limiting.

FIG. 6B shows a top down view for device 200 at the elevation indicated in FIG. 2T by view line 6B. In that regard, FIG. 6B shows a top down view at a level in device 200 through portions 206′ of silicide blocking layer 206. As shown, capacitor dielectric layer 220 and conductive plugs 221 are formed through dielectric liner 208 and portions 206′ of silicide blocking layer 206, as described above.

FIG. 6C shows a top down view for device 200 at the elevation indicated in FIG. 2T by view line 6C. In that regard, FIG. 6C shows a top down view at a level in device 200 positioned under PMD 210 and through dielectric liner 208. As shown, capacitor dielectric layer 220, conductive plugs 221, and contacts 230 are formed through dielectric liner 208 and portions 206′ of silicide blocking layer 206, as described above.

FIG. 6D shows a top down view for device 200 at the elevation indicated in FIG. 2T by view line 6D. In that regard, FIG. 6D shows a top down view at a level in device 200 positioned under dielectric liner 208 and through silicide layer 204 and substrate 202. As shown, capacitor dielectric layer 220 and conductive plugs 221 are laterally surrounded by silicide layer 204 and portions of substrate 202 at the same elevation, as described above. As shown, portions of substrate 202 prevent silicide layer 204 from interfacing with capacitor dielectric layer 220. Additionally, FIG. 6D shows silicide layer 204 ending at isolation feature 266 in device 200.

Referring now to FIG. 6D′ and 2T′, FIG. 6D′ shows a top down view for device 200′ at the elevation indicated in FIG. 2T′ by view line 6D′. In that regard, FIG. 6D′ shows a top down view at a level in device 200′ positioned at the same elevation as FIG. 6D. In contrast to the device 200 at this elevation, the silicide layer 204 extends to the dielectric layer 220 due to the absence of silicide blocking layer 206. As such, capacitor dielectric layer 220 interfaces with silicide layer 204, as described above.

FIG. 6E shows a top down view for device 200 at the elevation indicated in FIG. 2T by view line 6E. In that regard, FIG. 6E shows a top down view at a level in device 200 positioned through substrate 202. As shown, capacitor dielectric layer 220 and conductive plugs 221 are formed through substrate 202, as described above.

In various examples, steps 110 and 112 may be performed simultaneously with the contact formation of contacts to other FEOL features and components. In various examples, steps 110 and 112 may be performed as described above when a silicon trench capacitor such as described herein is not being formed. In that regard, the silicon trench capacitor described herein is modular and can be added or removed form integrated semiconductor devices with little to no change to the processes used for other components.

At step 114 of FIG. 1, a metal layer is formed over the PMD to connect to the conductive plugs and the contacts. As shown in FIG. 2U, device 200 is illustrated including trench capacitor 240, a FET 250, and a patterned metal layer 232 connected to the various shown components. When connected by patterned metal layer 232 conductive plugs 221 function as capacitor plate 222. Trench capacitor 240 is formed by steps 102-112 of method 100 as part of BEOL processing, as described above. FET 250 is formed during FEOL processing prior to step 102 of method 100, as described above. Moreover, FIG. 2U follows the process of device 200 from FIG. 2S where the capacitor dielectric layer 220 is disposed over the PMD 210 such that patterned metal layer 232 is formed on capacitor dielectric layer 220. A such, capacitor dielectric layer 220 is positioned between patterned metal layer 232 and the top surface of PMD 210. In various examples, patterned metal layer 232 may include a metal and/or metal alloy. In various examples, the metal and/or metal alloy may be or include Al, Cu, aluminum-copper alloy (AlCu), or the like.

FET 250 includes a doped well 252, a first source/drain region 254, a second source/drain region 256, a gate stack 258, a first source/drain contact 260, a second source/drain contact 262, a gate contact 264, and an isolation feature 266. As shown, doped well 252 is disposed in substrate 202 under first source/drain region 254, second source/drain region 256, and gate stack 258. In various examples, one or more doping processes may be performed to the semiconductor substrate to form doped well 252. Doped well 252 includes an N-type dopant or a P-type dopant and, in various examples, may be lightly doped or heavily doped. In various examples, doped well 252 may have an opposite doping of substrate 202 of trench capacitor 240.

First source/drain region 254 and second source/drain region 256 may be disposed in or on substrate 202. In various examples, one or more materials may be formed, deposited, or grown on substrate 202 to form first source/drain region 254 and second source/drain region 256. For example, an etching process may be performed on substrate 202 to form recesses in which an epitaxial growth process is then performed to grow a semiconductor material to form first source/drain region 254 and second source/drain region 256. In other examples, substrate 202 is doped to form first source/drain region 254 and second source/drain region 256. In various examples, first source/drain region 254 and second source/drain region 256 may undergo a doping process, such as for example, one or more ion implantation processes. First source/drain region 254 and second source/drain region 256 may be doped with p-type dopants or n-type dopants depending on the desired design requirements. Additionally, as shown, silicide layer 204 is disposed on first source/drain region 254 and second source/drain region 256.

Gate stack 258 is disposed over substrate 202 between first source/drain region 254 and second source/drain region 256. Gate stack 258 (e.g., gate structure) may include a gate dielectric layer and a gate electrode layer. The gate dielectric layer may include any gate dielectric material including a high-k dielectric material (e.g., dielectric constant greater than silicon oxide). In various examples, the gate dielectric material layer may include materials such as silicon oxide, hafnium oxide, and/or zirconium oxide. The gate electrode layer may include any gate electrode material layer(s). In various examples the gate electrode layer may include, polycrystalline silicon, also referred to as polysilicon. In other examples, the gate electrode layer may include other metals and metal alloys. For example, the gate electrode layer may include metal alloys such as TiN and/or TaN. In other examples, the gate electrode layer may include Cu, W, and/or Al.

First source/drain contact 260 and second source/drain contact 262 extend through capacitor dielectric layer 220, PMD 210, dielectric liner 208 and to silicide layer 204 disposed over first source/drain region 254 and second source/drain region 256, respectively. Gate contact 264 extends through capacitor dielectric layer 220, PMD 210, and dielectric liner 208 and to gate stack 258. In some examples, first source/drain contact 260, second source/drain contact 262 and gate contact 264 may be formed during the same process discussed above with respect to the formation of contacts 230. In other examples, first source/drain contact 260, second source/drain contact 262 and gate contact 264 may be formed during another BEOL process that occurs before and/or after the formation of contacts 230 as discussed above. In various examples, first source/drain contact 260, second source/drain contact 262 and gate contact 264 may each include (i) one or more metal-barrier and/or adhesion layers (e.g., TiN, TaN, the like, or a combination thereof) conformally in a respective trench through dielectric liner 208 and (ii) a fill metal (e.g., Al, Cu, W, the like, or a combination thereof) over and/or on the metal-barrier and/or adhesion layer(s).

As shown, isolation feature 266 provides electrical isolation between the respective portions of substrate containing the trench capacitor 240 and the FET 250. In various examples, isolation feature 266 may include a shallow trench isolation (STI) structure and/or a deep trench isolation structure. Isolation feature 266 electrically isolates trench capacitor 240 from FET 250. In various examples, isolation feature 266 may include dielectric materials providing electrical isolation such a silicon oxide, silicon nitride, silicon oxynitride, the like, and/or a combination thereof.

As shown in FIG. 2U, and in various examples, patterned metal layer 232 of device 200 is formed over capacitor dielectric layer 220, capacitor plate 222, and the various contact features (e.g., first source/drain contact 260, second source/drain contact 262, gate contact 264 and contacts 230). More specifically, in some examples, patterned metal layer 232 of device 200 is formed directly on the respective top surfaces of capacitor dielectric layer 220, capacitor plate 222, and the various contact features (e.g., first source/drain contact 260, second source/drain contact 262, gate contact 264 and contacts 230). Specifically, in some examples, patterned metal layer 232 is formed over trench capacitor 240 and physically contacts capacitor dielectric layer 220, capacitor plate 222, and contacts 230. Additionally, in some examples, patterned metal layer 232 is further formed over FET 250 and physically contacts capacitor dielectric layer 220, first source/drain contact 260, second source/drain contact 262, and gate contact 264 associated with FET 250. In various examples, one or more portions of patterned metal layer 232 may contact both trench capacitor 240 and FET 250. As shown, patterned metal layer 232 includes respective metal lines 233a-e that are connected to first source/drain contact 260, gate contact 264, second source/drain contact 262, contacts 230, and capacitor plate 222 of trench capacitor 240.

Unlike trench capacitors formed during FEOL process steps, the formation of trench capacitor 240 during BEOL processes advantageously allows for a first metal layer (e.g. M1 layer) to be directly connected to conductive plugs 221 of the capacitor plate 222 of trench capacitor 240. That is, the BEOL process formation of trench capacitor 240 allows the top plate (e.g. capacitor plate 222) of the trench capacitor to be directly connected to the first metal layer (e.g., metal layer 1) without the use of conductive vias and/or additional contacts. Because of this, capacitor density may be increased as there are no contact placement alignment tolerance issues that are normally associated with balancing the trench capacitor being formed during FEOL process steps with conductive vias and/or contacts being formed during BEOL process to connect to the trench capacitor.

In other examples, as shown in FIG. 2V, the process for device 200 may alternatively proceed from FIG. 2T to FIG. 2V in forming patterned metal layer 232 over device 200. Device 200 in FIG. 2V is similar to device 200 in FIG. 2U except with respect to capacitor dielectric layer 220. Unlike FIG. 2U, capacitor dielectric layer 220 has been removed from the top surface of PMD 210 at some point during the process disclosed by method 100 (see FIGS. 2L and 2T) for device 200 shown in FIG. 2V. As such, patterned metal layer 232 is formed over PMD 210, capacitor plate 222, and the various contact features (e.g., first source/drain contact 260, second source/drain contact 262, gate contact 264 and contacts 230). More specifically, in some examples, patterned metal layer 232 of device 200 is formed directly on the respective top surfaces of PMD 210, capacitor plate 222, the capacitor dielectric layer 220 lining the capacitor plate, and the various contact features (e.g., first source/drain contact 260, second source/drain contact 262, gate contact 264 and contacts 230). As such, in some examples, patterned metal layer 232 is formed over trench capacitor 240 and physically contacts PMD 210, capacitor dielectric layer 220, capacitor plate 222, and contacts 230. Additionally, in some examples, patterned metal layer 232 is further formed over FET 250 and physically contacts PMD 210, first source/drain contact 260, second source/drain contact 262, and gate contact 264. In various examples, one or more portions of patterned metal layer 232 may contact both trench capacitor 240 and FET 250.

FIGS. 2W and 2X, show device 200′ after having gone through steps 102-114 of method 100. As described above, device 200′ differs from device 200 in the lack of a silicide blocking layer being used during the processing steps of method 100. The lack of a silicide blocking may result in silicide layer 204 interfacing (e.g. physically contacting) portions of trench capacitor 240. Specifically, in some examples as shown in FIGS. 2W and 2X, and in plan view FIG. 6D′, silicide layer 204 interfaces (e.g. physically contacts) capacitor dielectric layer 220 of trench capacitor 240 in device 200′ shown in FIGS. 2W and 2X.

Moreover, FIG. 2W follows the process of device 200′ from process steps similar to those shown in FIG. 2S where the capacitor dielectric layer 220 is disposed over the PMD 210 such that patterned metal layer 232 is formed on capacitor dielectric layer 220. A such, capacitor dielectric layer 220 is positioned between patterned metal layer 232 and the top surface of PMD 210. Additionally, FIG. 2X follows the process of device 200′ from process steps similar to those shown in FIG. 2T where the capacitor dielectric layer 220 has been removed from the top surface of PMD 210 at some point during the process disclosed by method 100 (see FIGS. 2L and 2T). As such, patterned metal layer 232 is formed on PMD 210, capacitor plate 222, and the various contact features (e.g., first source/drain contact 260, second source/drain contact 262, gate contact 264, and contacts 230). All other features of device 200′ in FIGS. 2W and 2X are similar to the features of device 200 described above with respect to FIGS. 2U and 2V, respectively. For brevity, and clarity, similar features between device 200 and 200′ are not repeated here again.

Accordingly, the steps of method 100, as described above with reference to FIGS. 2A-2X, provide steps for forming a trench capacitor during BEOL. That is, after forming other components such as transistors, resistors, inductors, and other capacitors, after forming a PMD over the device, and before forming the metal connections between the various components, trench capacitors are formed. In various examples, trench capacitors formed using the steps of method 100 may have a higher capacitor density for a given voltage node or breakdown requirement.

Additionally, there is reduced risk of defect formation in the trench capacitor due to being formed during the lower temperatures used in the BEOL processing as compared to the higher temperatures used during FEOL processing steps. Other advantages include connecting the top plate of the trench capacitor directly to metal lines (e.g., metal layer 1) without the use of vias and/or additional contacts. That is, the disclosed process forms the first metal layer (e.g., M1 layer) of the BEOL metallization process directly on the capacitor plate (e.g., the top plate). This in contrast to trench capacitors formed during FEOL processing steps as the first metal layer (e.g., M1 layer) of the BEOL metallization process is not formed directly on the capacitor plate (e.g., the top plate), but instead formed on an intervening conductive vias that are first formed on the capacitor plate. Because of this, the capacitor density may be increased as there are no conductive via (e.g., contact) placement alignment tolerance issues. Therefore, the trenches of the capacitor may be more densely packed. The increased density occurs because the trenches used to form the capacitor plate may be narrower for a given manufacturing node. The narrower trench width increases the capacitance per unit area. Furthermore, forming the top plate of the trench capacitor of a metal (e.g., tungsten) lowers the serial resistance of the trench capacitor as compared to a poly core. The metal may be used due to the lower processing temperatures of the BEOL processes. Accordingly, the silicon trench capacitor described herein is modular, flexible, and may be tailored to fit within the design parameters of a variety of integrated semiconductor devices.

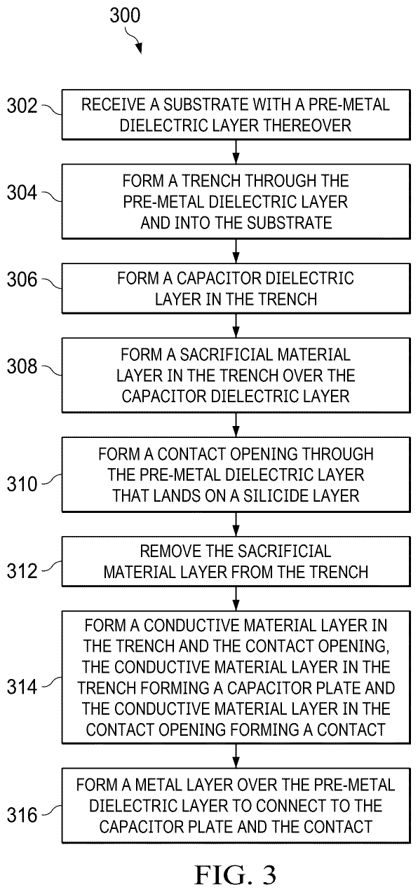

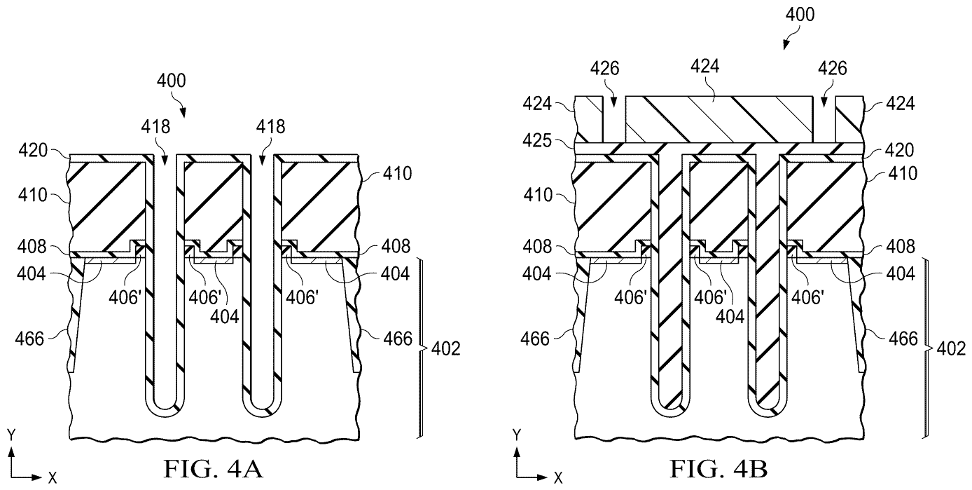

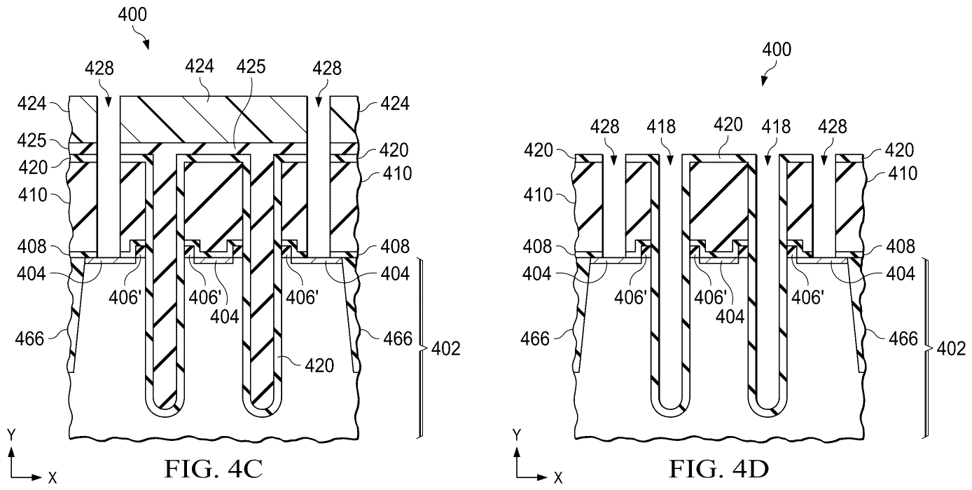

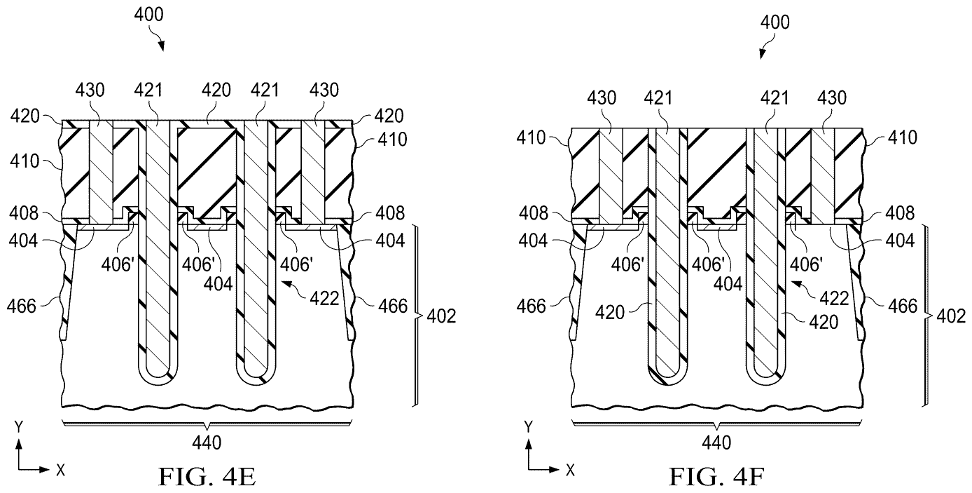

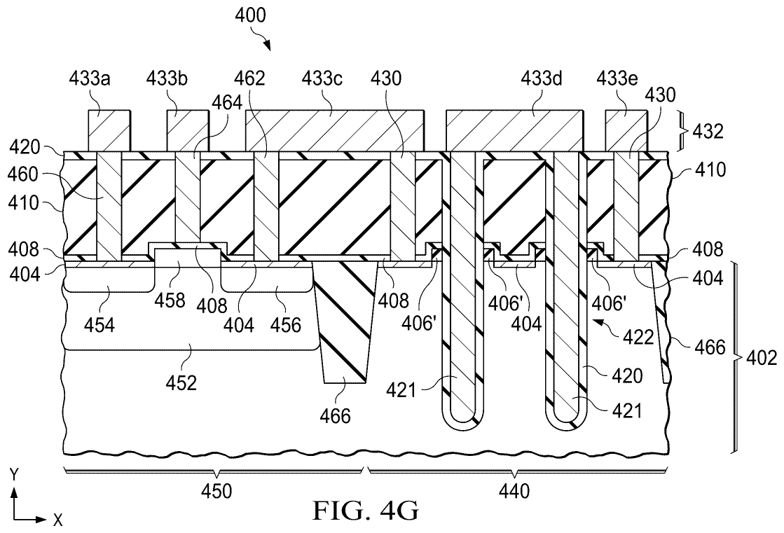

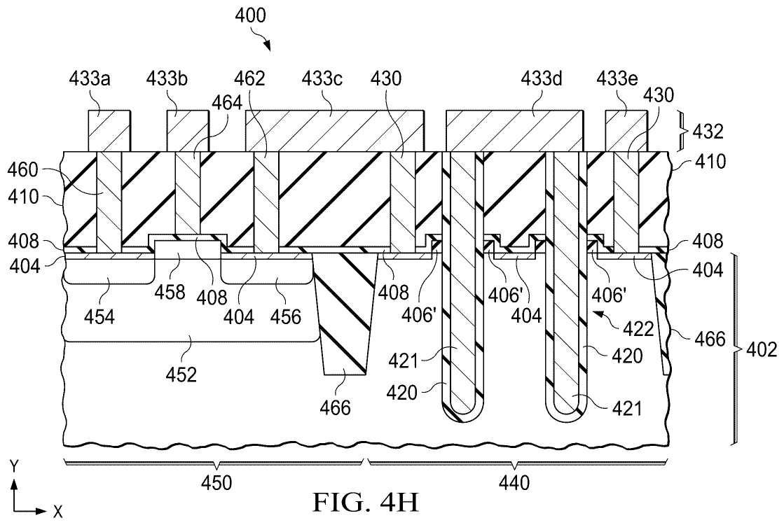

Referring now to FIG. 3, a flow diagram of a method 300 for forming a trench capacitor in a substrate during BEOL processing is illustrated, in accordance with various examples of the present disclosure. Prior to the steps of method 300 the substrate has completed FEOL processing. Typically, FEOL processing includes forming integrated circuit components including transistors, resistors, capacitors, inductors, etc., and BEOL processing includes forming silicide layers and metal interconnects to connect each of the integrated circuit components. In various examples, and as used throughout below description, the transistors may include FETs, bipolar transistors, BiCMOS transistors, other transistors, or a combination thereof. Additional processes can be provided before, during, and after method 300. As discussed below, method 300 is described with reference to FIGS. 4A-4H.

In that regard, FIGS. 4A-4H are diagrammatic cross-sectional views of a device 400 at various stages of fabrication (such as those associated with method 300 of FIG. 3) according to various aspects of the present disclosure. In various examples, device 400 may be an integrated circuit having completed FEOL processing where transistors, resistors, inductors, capacitors, and/or other components were formed during various processing steps before the steps of method 300. For ease of discussion, FIGS. 4A-4F are illustrated and described without showing other components of the integrated circuit of device 400. FIGS. 4G and 4H illustrate a FET adjacent to the trench capacitor that is formed by method 300 and illustrated in FIGS. 4A-4F. Additional features can be added to device 400 and some features described below can be replaced, modified, or eliminated in other examples of device 400.

Device 400 includes similar layers as device 200 described above in FIGS. 2A-2X, including a substrate 402, a silicide layer 404, a silicide blocking layer 406, a dielectric liner 408, a PMD 410, a capacitor dielectric layer 420, a patterned photoresist layer 424, conductive plugs 421, a capacitor plate 422, contacts 430, and a patterned metal layer 432, descriptions of which may not be repeated below. In various examples, device 400 may be formed without silicide blocking layer 406, similar to various examples of device 200 described above.

At step 302 of FIG. 3, a substrate with a PMD thereover is received for BEOL processing. The substrate is received after completing FEOL processing steps, such as for example, forming transistors, resistors, capacitors, inductors, and/or other components and after completing one or more BEOL processes. As shown in FIG. 4A, device 400 is received after completing FEOL processing and one or more BEOL processes. In some examples, one or more transistors, resistors, capacitors, inductors, and/or other components (e.g., FET 450 in FIGS. 4G and 4H) are formed on device 400 during FEOL processing. In some examples, a silicide layer, dielectric layer, and/or other BEOL material layers may be formed over device 400. Accordingly, in various examples, device 400 includes silicide layer 404 and silicide blocking layer 406 formed over a top surface of substrate 402. In various examples, silicide layer 404 and silicide blocking layer 406 may be interspersed along a top surface of substrate 402 as shown in FIG. 4A. Dielectric liner 408 is formed over both silicide layer 404 and silicide blocking layer 406 and PMD 410 is formed over dielectric liner 408.

At step 304 of FIG. 3, a trench is formed through the PMD and into the substrate. For clarity and brevity, device 400 shown in FIG. 4A is similar to device 200 shown in FIG. 2I. That is, the process described above with respect to method 100 used to form device 200 shown in FIG. 2I may similarly be used to form device 400 shown in FIG. 4A. As such, the process streps used to form device 400 shown in FIG. 4A are similar to those discussed above with respect to FIGS. 2A-2I. As shown in FIG. 4A, extended trenches 418 are formed through PMD 410, dielectric liner 408, and silicide blocking layer 406 and into substrate 402. Extended trenches 418 may be formed using one or more etching processes. In various examples, the one or more etching processes may be similar to those described above in FIGS. 2C-2H.

At step 306 of FIG. 3, a capacitor dielectric layer is formed in the trench. Continuing with FIG. 4A, capacitor dielectric layer 420 may be formed over PMD 410 and in extended trenches 418. Specifically, capacitor dielectric layer 420 may be formed along sidewalls of PMD 410, sidewalls of dielectric liner 408, sidewalls of silicide blocking layer 406, and sidewalls and bottom surfaces of extended trenches 418. In various examples, capacitor dielectric layer 420 may be formed using similar processes to those described above in FIGS. 2I and 2J with respect to forming capacitor dielectric layer 220.

At step 308 of FIG. 3, a sacrificial material layer is formed in the trench over the capacitor dielectric layer. As shown in FIG. 4B, a sacrificial layer 425 is formed in extended trenches 418 including over capacitor dielectric layer 420. In various examples, sacrificial layer 425 fills extended trenches 418 (e.g., up to and/or above a top surface of PMD 410 and/or capacitor dielectric layer 420). After filling extended trenches 418 with sacrificial layer 425, patterned photoresist layer 424 is formed over device 400. Specifically, patterned photoresist layer 424 is formed over sacrificial layer 425 and capacitor dielectric layer 420. In various examples, sacrificial layer 425 may be an anti-reflective coating material such as a bottom anti-reflective coating (BARC) material. In other examples, sacrificial layer 425 may be a photoresist material. In other examples, sacrificial layer 425 may be a combination of an anti-reflective coating material and a photoresist material. In various examples, patterned photoresist layer 424 and sacrificial layer 425 may be the same material or have different material compositions. In various examples, patterned photoresist layer 424 and sacrificial layer 425 may be formed using the same or different processes. First openings 426 are formed through patterned photoresist layer 424, exposing sacrificial layer 425. In various examples, first openings 426 are offset from sacrificial layer 425 filling extended trenches 418. In other words, first openings 426 are formed over portions of silicide layer 404 that are covered by various layers including portions of capacitor dielectric layer 420 disposed over the top surface of PMD 410.

At step 310 of FIG. 3, a contact opening is formed through the PMD that lands on a silicide layer. As shown in FIG. 4C, contact openings 428 are formed through sacrificial layer 425, capacitor dielectric layer 420, PMD 410, and dielectric liner 408 to expose portions of silicide layer 404. In various examples, contact openings 428 may be formed using one or more etching processes. In various examples, contact openings 428 (e.g., contact holes) may be formed similar to contact openings 228 described above in FIGS. 2O and 2P of method 100. As shown in FIG. 4C, and in some examples, contact openings 428 expose a top surface of silicide layer 404.

At step 312 of FIG. 3, the sacrificial material layer is removed from the trench. As shown in FIG. 4D, patterned photoresist layer 424 and sacrificial layer 425 are removed from device 400, exposing capacitor dielectric layer 420 inside extended trenches 418 as well as exposing portions of capacitor dielectric layer 420 disposed over PMD 410 that were previous covered by patterned photoresist layer 424 and/or sacrificial layer 425. In various examples, patterned photoresist layer 424 may be removed using one or more processes and sacrificial layer 425 may be removed using one or more different processes. In various examples, patterned photoresist layer 424 and sacrificial layer 425 may be removed using the same one or more processes. In various examples, the one or more processes may include plasma ashing, a wet resist strip chemical, piranha solution (H₂SO₄ and H₂O₂), other suitable processes, or combinations thereof.

At step 314 of FIG. 3, a conductive material layer is formed in the trench and the contact opening to form a capacitor plate in the trench and a contact in the contact opening. As shown in FIG. 4E, a conductive material layer (e.g., electrically conductive trench-fill material layer(s) and/or barrier layers) is formed over capacitor dielectric layer 420 and in extended trenches 418 and contact openings 428. A planarization process (e.g., a CMP process) is then performed to remove overburden portions of the conductive material layer to form conductive plugs 421 and contacts 430. As shown, after the planarization process of the conductive material layer, the one or more conductive plugs 421 are disposed in extended trenches 418. The one or more conductive plugs 421 form capacitor plate 422 after being electrically coupled together, as described further below.

In some examples, as shown in FIG. 4E, the planarization process removes portions of the overburden of the conductive material layer (e.g., electrically conductive trench-fill material layer(s) and/or barrier layers) and exposes portions of capacitor dielectric layer 220 that are disposed over the top surface of PMD 210. In some other examples, as shown in FIG. 4F, the planarization process removes portions of the overburden of the conductive material layer (e.g., electrically conductive trench-fill material layer(s) and/or barrier layers) as well as portions of capacitor dielectric layer 220 that are disposed over PMD 210 to expose PMD 210. Because, in some examples, conductive plugs 421 and contacts 430 are formed during the same process these features may have the same material compositions. In various examples, conductive plugs 421 and contacts 430 may include similar materials as those described above in FIGS. 2K, 2L, 2S, and 2T.

As a result of the formation of capacitor plate 422, a trench capacitor 440 is formed in device 400. Specifically, conductive plugs 421 and substrate 402 function as the capacitor plates of trench capacitor 440. In that regard, as discussed above, and similar to substrate 202, substrate 402, including epitaxially grown layers disposed thereon, may have doped regions (or wells) formed therein such that these doped regions of substrate 402 form a first capacitor plate (e.g., bottom capacitor plate) of trench capacitor 440. Also, in some examples, capacitor plate 422 forms a second plate (e.g. top capacitor plate) of trench capacitor 440. As shown, trench capacitor 440 further includes capacitor dielectric layer 420 positioned between substrate 202 (e.g., first capacitor plate) and capacitor plate 422 (e.g. second capacitor plate) thereby isolating the two layers from each other.

Still further, device 400 includes portions 406′ of silicide blocking layer 406 that interface with capacitor dielectric layer 420. As a result, the distance between silicide layer 404 and conductive plug 421 is increased, in-part, because of portions 406′ of silicide blocking layer 406. That is, these portions 406′ of silicide blocking layer 206 increase the distance (e.g. dielectric buffer) between the silicide layer 404 and the conductive plugs 421. In some examples, the remaining portions 406′ of silicide blocking layer 406 prevents silicide layer 204 from being exposed during trench etching processes which may reduce cross contamination of the silicide materials from silicide layer 404 into substrate 402 (e.g., incorporation of silicide materials in trench walls). In various examples, reducing cross contamination improves the quality of the silicon trench capacitor (e.g., higher breakdown voltage, less current leakage, etc.).

At step 316, a metal layer is formed over the PMD to connect the capacitor plate and the contact. As shown in FIGS. 4G and 4H, device 400 is illustrated including trench capacitor 440 and a FET 450. Trench capacitor 440 is formed by steps 302-316 of method 300 as part of BEOL processing, as described above. FET 450 is formed during FEOL processing prior to step 302 of method 300, as described above. FET 450 includes features similar to those described above with respect to FET 250 and may not be described again here. For example, FET 450 includes a doped well 452, a first source/drain region 454, a second source/drain region 456, a gate stack 458, a first source/drain contact 460, a second source/drain contact 462, a gate contact 464, and an isolation feature 466. In various examples, isolation feature 466 may include a shallow trench isolation (STI) structure and a deep trench isolation structure. Isolation feature 466 electrically isolates trench capacitor 440 from FET 450.

As shown in FIG. 4G, and in various examples, a patterned metal layer 432 is formed over capacitor dielectric layer 420 disposed over PMD 410. Specifically, FIG. 4G follows the process of device 400 from FIG. 4E where the capacitor dielectric layer 420 is disposed over the PMD 410 such that patterned metal layer 432 is formed on capacitor dielectric layer 420. A such, capacitor dielectric layer 420 is positioned between patterned metal layer 432 and the top surface of PMD 410.

As shown, patterned metal layer 432 is formed over trench capacitor 440 such that patterned metal layer 432 physically contacts capacitor dielectric layer 420, conductive plugs 421, and contacts 430. The conductive plugs 421 connected in parallel by the patterned metal layer 432 act as the capacitor plate 422. Patterned metal layer 432 is further formed over FET 450 such that patterned metal layer 432 physically contacts capacitor dielectric layer 420, first source/drain contact 460, second source/drain contact 462, and gate contact 464. In various examples, one or more portions of patterned metal layer 432 may contact both trench capacitor 440 and FET 450. As shown, patterned metal layer 432 includes respective metal lines 433a-e that are connected to first source/drain contact 460, gate contact 464, second source/drain contact 462, contacts 430, and conductive plugs 421of trench capacitor 240.

Unlike trench capacitors formed during FEOL process steps, the formation of trench capacitor 440 during BEOL processes advantageously allows for the first metal layer (e.g. M1 layer) of the BEOL metallization process to be directly connected to conductive plugs 421of trench capacitor 440. That is, the BEOL process formation of trench capacitor 440 allows the top plate (e.g. capacitor plate 422) of the trench capacitor to be directly connected to the first metal layer (e.g., M1 layer) without the use of conductive vias and/or additional contacts. Because of this, capacitor density may be increased as there are no contact placement alignment tolerance issues that are normally associated with balancing the trench capacitor being formed during FEOL process steps with conductive vias and/or contacts being formed during BEOL process to connect to the trench capacitor.

In other examples, as shown in FIG. 4H, the process for device 400 may alternatively proceed from FIG. 4F to FIG. 4H in forming patterned metal layer 432 over device 400. Device 400 in FIG. 4H is similar to device 400 in FIG. 4G except with respect to capacitor dielectric layer 420. Unlike FIG. 4G, capacitor dielectric layer 420 has been removed from the top surface of PMD 410 during the process disclosed by method 300 (see FIG. 4F) for device 400 shown in FIG. 4H. As such, patterned metal layer 432 is formed over PMD 410, capacitor plate 422 and the various contact features (e.g., first source/drain contact 460, second source/drain contact 462, gate contact 464 and contacts 430). More specifically, in some examples, patterned metal layer 432 of device 400 is formed directly on the respective top surfaces of PMD 410, capacitor plate 422 and the capacitor dielectric layer 420 lining the capacitor plate, and the various contact features (e.g., first source/drain contact 460, second source/drain contact 462, gate contact 464 and contacts 430). As such, in some examples, patterned metal layer 432 is formed over trench capacitor 440 and physically contacts PMD 410, capacitor dielectric layer 420, capacitor plate 422, and contacts 430. Additionally, in some examples, patterned metal layer 432 is further formed over FET 450 and physically contacts PMD 410, first source/drain contact 460, second source/drain contact 462, and gate contact 464. In various examples, one or more portions of patterned metal layer 432 may contact both trench capacitor 440 and FET 450.

Accordingly, the steps of method 300, as described above with reference to FIGS. 4A-4H, provide steps for forming a trench capacitor during BEOL. That is, after forming other components such as transistors, resistors, inductors, and other capacitors, after forming a PMD over the device, and before forming the metal connections between the various components, trench capacitors are formed. Trench capacitors formed using the steps of method 300 have an improved high-voltage breakdown for the capacitor density. Additionally, there is reduced risk of defect formation in the trench capacitor due to being formed during the lower temperatures used in the BEOL processing as compared to the higher temperatures used during FEOL processing steps. Other advantages include connecting the top plate of the trench capacitor directly to metal lines (e.g., metal layer 1) without the use of vias and/or additional contacts. That is, the disclosed process forms the first metal layer (e.g., M1 layer) of the BEOL metallization process directly on the capacitor plate (e.g., the top plate). This in contrast to trench capacitors formed during FEOL processing steps as the first metal layer (e.g., M1 layer) of the BEOL metallization process is not formed directly on the capacitor plate (e.g., the top plate), but instead formed on intervening conductive vias that are first formed on the capacitor plate. Because of this, the capacitor density may be increased as there are no conductive via (e.g., contact) placement alignment tolerance issues. Furthermore, forming the top plate of the trench capacitor of a metal (e.g., tungsten) lowers the serial resistance of the trench capacitor as compared to a polysilicon core. The metal material for the capacitor plate (e.g., top plate) may be used due to the lower processing temperatures of the BEOL processes.

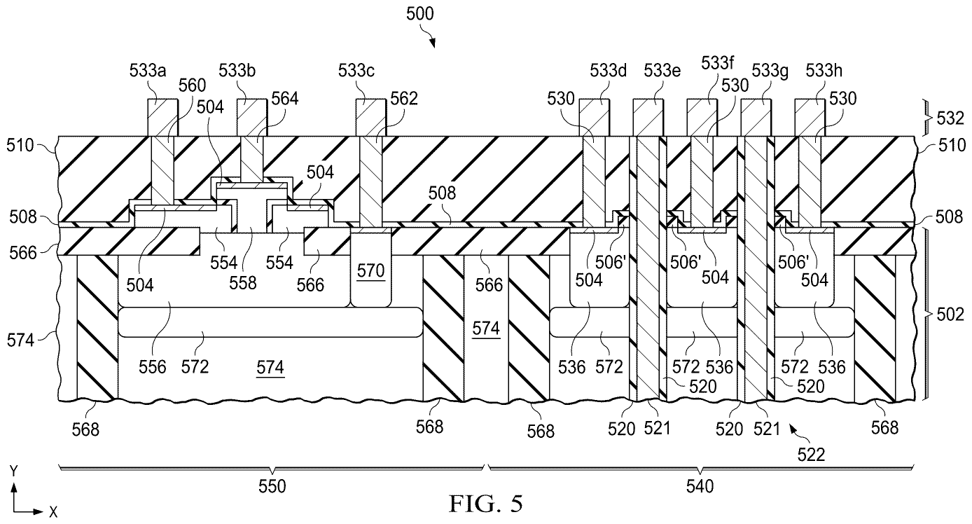

Referring now to FIG. 5, a device 500 is illustrated in accordance with various examples of the present disclosure. Device 500 may be formed using either method 100 or method 300. Similar to device 200 and device 400, device 500 includes a trench capacitor 540 and a bipolar transistor 550. Trench capacitor 540 and bipolar transistor 550 may, in various examples, be formed over an n-type buried layer 572 that is formed over a p-type substrate 574. In various examples, p-type substrate 574 may include one or more semiconductor layers. In various examples, p-type substrate 574 may be doped with one or more p-type dopants such as boron. N-type buried layer 572 is formed over p-type substrate 574. In various examples, n-type buried layer 572 may be doped with one or more n-type dopants such as arsenic, phosphorous, and antimony.

Device 500, and more specifically, trench capacitor 540 further includes similar layers as device 200 and device 400 described above, including a substrate 502, a silicide layer 504, a silicide blocking layer 506, a dielectric liner 508, a PMD 510, a capacitor dielectric layer 520, conductive plugs 521, a capacitor plate 522, contacts 530, and a patterned metal layer 532, descriptions of which will not be repeated below. Trench capacitor 540 further includes a deep n-well 536 formed in substrate 502. Deep n-well 536 form one plate of trench capacitor 540. In various examples, deep n-well 536 may be doped with one or more n-type dopants such as arsenic, phosphorous, and antimony. In various examples, deep n-well 536 extend from silicide layer 504 to n-type buried layer 572.

Bipolar transistor 550 includes a base region 554, a collector region 556, an emitter region 558, a base contact 560, a collector contact 562, an emitter contact 564, shallow trench isolation structures 566, deep trench isolation structures 568, and a deep collector region 570.

Collector region 556 is formed over n-type buried layer 572. In various examples, collector region 556 may be doped using one or more n-type dopants such as arsenic, phosphorous, and antimony. In various examples, collector region 556 may have a higher dopant concentration than n-type buried layer 572. In various examples, as shown in FIG. 5, bipolar transistor 550 may include deep collector region 570 that over which silicide layer 504 is formed. In various examples, deep collector region 570 extends from silicide layer 504 to n-type buried layer 572. In various examples, deep collector region 570 may have a higher dopant concentration than collector region 556. Base region 554 is formed over collector region 556. Base region 554 may be doped with one or more p-type dopants such as boron. Emitter region 558 is formed over base region 554. Emitter region 558 may be doped with one or more n-type dopants. In various examples, emitter region 558 may have a higher dopant concentration than collector region 556. In various examples, bipolar transistor 550 may alternatively include a PNP transistor using a p-type buried layer. Other alternative bipolar transistor designs are possible and are within the scope of this disclosure.

Base contact 560, collector contact 562, and emitter contact 564 may be formed using similar processes as capacitor plate 522 and/or contacts 530. For examples, base contact 560, collector contact 562, and/or emitter contact 564 may include (i) one or more metal-barrier and/or adhesion layers (e.g., Ti, Ta, TiN, TaN, the like, or a combination thereof) conformally in a respective contact openings 228 and (ii) a fill metal (e.g., Al, Cu, W, the like, or a combination thereof) over and/or on the metal-barrier and/or adhesion layer(s). As shown, patterned metal layer 532 includes respective metal lines 533a-h that are connected to base contact 560, collector contact 562, emitter contact 564, contacts 530, and capacitor plate 522 of trench capacitor 540. Specifically, metal lines 533d, 533, and 533h are connected to contacts 530 and metal lines 533e and 533g are connected to conductive plugs 521 of capacitor plate 522. As previously described, a first plate of trench capacitor 540 (e.g., a bottom plate) is formed by deep n-well 536 and a second plate of trench capacitor 540 (e.g., a top plate) is formed by capacitor plate 522 including conductive plugs 521.

Device 500 illustrates different structures that may be manufactured using method 100 and/or method 300. For example, device 500 includes bipolar transistor 550 as opposed to FET 450 of device 400 or FET 250 of device 200. However, trench capacitor 540 may be formed using similar processes as trench capacitors 240 and/or 440 during BEOL processing. Additionally, trench capacitor 540 includes an additional contact 530 disposed between conductive plugs 521 of capacitor plate 522. This additional contact feature(s) between portions of a capacitor plate (e.g., conductive plugs 521), as shown in FIG. 5, may be formed in all of the disclosed examples herein (e.g. devices 200, 200′, and/or 400). This illustrates the variations in structures that are possible using the methods described herein. The methods described herein are modular and capable of being added to the BEOL processing of many semiconductor devices with little to no alteration of the layout of the various components of the semiconductor devices.

Accordingly, the methods described herein provide steps for forming devices including a trench capacitor formed during BEOL processing BEOL. That is, after forming other components such as transistors, resistors, inductors, and other capacitors, after forming a PMD over the device, and before forming the metal connections between the various components. Forming trench capacitors during BEOL processing, as described herein, improves capacitor density within semiconductor devices for a given breakdown requirement. Specifically, the metal lines (e.g. metal layer 1) are formed directly on the top plate of the trench capacitor. This removes the constraints and alignment tolerances issues associated with vias used to connect components to the metal lines. Additionally, there is reduced risk of defect formation in the trench capacitor due to the lower temperatures used in the BEOL processing.

Finally, it should be understood that any of the above-described concepts can be used alone or in combination with any or all of the other above-described concepts. Although various examples have been disclosed and described, it is understood, recognized, and/or contemplated that certain modifications would come within the scope of this disclosure. Accordingly, the description is not intended to be exhaustive or to limit the principles described or illustrated herein to any precise form. Many modifications and variations are possible in light of the above teaching.

What is claimed is:

1. A method of forming an integrated circuit, comprising:
forming an electronic device over a substrate, the substrate including a semiconductor material;
forming a pre-metal dielectric layer over the electronic device;
forming a trench through the pre-metal dielectric layer and into the substrate;
forming a capacitor dielectric layer over the pre-metal dielectric layer and within the trench; and
forming a conductive material layer over the capacitor dielectric layer and within the trench, wherein the conductive material layer forms a first plate of a trench capacitor and the semiconductor material of the substrate forms a second plate of the trench capacitor.

2. The method of claim 1, further comprising:
forming a silicide layer over the substrate;
after forming the conductive material layer, forming a contact opening through the pre-metal dielectric layer exposing a portion of the silicide layer; and
forming a contact feature within the contact opening over the silicide layer.

3. The method of claim 2, wherein forming the contact opening through the pre-metal dielectric layer to expose the portion of the silicide layer further includes forming the contact opening through the capacitor dielectric layer such that a portion of the capacitor dielectric layer is removed during forming of the contact opening.

4. The method of claim 1, further comprising:
forming a silicide layer over the substrate; and
after forming the trench through the pre-metal dielectric layer and into the substrate, forming a contact opening through the pre-metal dielectric layer exposing the silicide layer, and
wherein forming the conductive material layer further includes forming the conductive material layer in the contact opening over the silicide layer.

5. The method of claim 1, further comprising:
forming a metal line directly on the conductive material layer disposed within the trench.

6. The method of claim 1, further comprising:
forming a silicide blocking layer over the substrate, wherein forming the trench through the pre-metal dielectric layer and into the substrate includes forming the trench through the silicide blocking layer, and
wherein the capacitor dielectric layer interfaces with the silicide blocking layer after forming the capacitor dielectric layer over the pre-metal dielectric layer and within the trench.

7. The method of claim 1, further comprising:
forming a silicide layer over the substrate, and
wherein the capacitor dielectric layer interfaces with the silicide layer after forming the capacitor dielectric layer over the pre-metal dielectric layer and within the trench.

8. The method of claim 1, wherein the conductive material layer includes a tungsten material.

9. A method comprising:
forming a silicide layer over a substrate;
forming a pre-metal dielectric layer over the silicide layer;
forming a trench through the pre-metal dielectric layer and into the substrate;
forming a capacitor dielectric layer over the pre-metal dielectric layer and within the trench; and
forming a conductive material layer over the capacitor dielectric layer and within the trench, wherein a portion of the conductive material layer extends through the pre-metal dielectric layer and into the substrate after forming the conductive material layer over the capacitor dielectric layer and within the trench, and wherein the conductive material layer forms a first plate of a trench capacitor and the substrate forms a second plate of the trench capacitor.

10. The method of claim 9, further comprising:
forming a metal line directly on the conductive material layer disposed within the trench.

11. The method of claim 10, further comprising:
planarizing, before forming the metal line, the capacitor dielectric layer and the conductive material layer to expose a top surface of the pre-metal dielectric layer, and
wherein forming the metal line directly on the conductive material layer disposed within the trench includes forming the metal line directly on the exposed top surface of the pre-metal dielectric layer.

12. The method of claim 9, further comprising:
forming a contact opening through the pre-metal dielectric layer exposing a portion of the silicide layer; and
forming a contact feature in the contact opening over the silicide layer.

13. The method of claim 9, further comprising:
forming a contact opening through the pre-metal dielectric layer to a portion of the silicide layer,
wherein forming the conductive material layer further includes forming the conductive material layer in the contact opening over the portion of the silicide layer.

14. The method of claim 13, further comprising:
forming, before forming the contact opening, a sacrificial layer in the trench; and
removing, before forming the conductive material layer, the sacrificial layer from the trench.

15. The method of claim 14, wherein the sacrificial layer includes anti-reflective coating layer.

16. A device comprising:
a pre-metal dielectric layer disposed over a substrate, the substrate including a semiconductor material;
a trench capacitor including:
a capacitor dielectric layer extending into a plurality of trenches formed through the pre-metal dielectric layer and into the substrate; and
a conductive material extending into the plurality of trenches; and
a metal layer disposed directly on the conductive material.

17. The device of claim 16, wherein the capacitor dielectric layer is disposed over the substrate between the metal layer and a top surface of the pre-metal dielectric layer.

18. The device of claim 16, wherein the metal layer directly contacts a top surface of the pre-metal dielectric layer.

19. The device of claim 16, further comprising:
a silicide layer disposed over the substrate; and
a contact feature extending to the silicide layer, and wherein the contact feature and the conductive material of the trench capacitor extend to substantially a same height above a top surface of the substrate.

20. The device of claim 16, further comprising:
a silicide layer disposed over the substrate; and
a silicide blocking layer disposed over the substrate adjacent the silicide layer, and
wherein the capacitor dielectric layer extends through and interfaces with the silicide blocking layer.
